(19) United States
(12) Patent Application Publication
(10) Pub. No.: US 2008/0121903 A1
(43) Pub. Date: May 29, 2008

(54) METHOD FOR MANUFACTURING LIGHT-EMITTING DIODE, LIGHT-EMITTING DIODE, LIGHTSOURCE CELL UNIT, LIGHT-EMITTING DIODE BACKLIGHT, LIGHT-EMITTING DIODE ILLUMINATING DEVICE, LIGHT-EMITTING DIODE DISPLAY, AND ELECTRONIC APPARATUS

(75) Inventors: Yuuji Hiramatsu, Kanagawa (JP); Nobukata Okano, Kanagawa (JP); Tomonori Hino, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 11/942,441

(22) Filed: Nov. 19, 2007

(30) Foreign Application Priority Data
Nov. 24, 2006 (JP) 2006-316885

(51) Int. Cl. H01L 33/00

(52) U.S. Cl. 257/89; 438/46; 257/98; 257/E33.067

(57) ABSTRACT

A light-emitting diode which has a significantly high luminous efficiency and which can be manufactured at a reasonable cost by one epitaxial growth and a manufacturing method thereof are provided. The above method includes: preparing a substrate provided with convex portions on one major surface, the convex portions being formed from a dielectric substance which is different from the substrate and which has a refractive index of 1.7 to 2.2; growing a first nitride-based III-V compound semiconductor layer in a concave portion on the substrate; growing a second nitride-based III-V compound semiconductor layer on the substrate from the first nitride-based III-V compound semiconductor layer in a lateral direction; and growing, on the second nitride-based III-V compound semiconductor layer, a first conductive type third nitride-based III-V compound semiconductor layer, an active layer, and a second conductive type fourth nitride-based III-V compound semiconductor layer.

### CROSS REFERENCES TO RELATED APPLICATIONS

The present invention contains subject matter related to Japanese Patent Application JP 2006-316885 filed in the Japanese Patent Office on Nov. 24, 2006, the entire contents of which are incorporated herein by reference.

### BACKGROUND OF THE INVENTION

1. Field of the Invention

The present invention relates to a method for manufacturing a light-emitting diode, a light-emitting diode, a light source cell unit, a light-emitting diode backlight, a light-emitting diode illuminating device, a light-emitting diode display, and an electronic apparatus, and more particularly, relates to a light-emitting diode using a nitride-based III-V compound semiconductor and to various devices and/or apparatuses using this light-emitting diode.

2. Description of the Related Art

When a GaN-based semiconductor is epitaxial-grown on a different type substrate such as a sapphire substrate, since the differences in lattice constant and coefficient of thermal expansion therebetween are large, crystal defects, in particular threading dislocations, occur at a high density.

In order to avoid this problem, heretofore, a technique to decrease the dislocation density by a selective lateral-direction growth has been widely used. In this technique, after a GaN-based semiconductor is epitaxially grown on a sapphire substrate or the like, the substrate is recovered from a crystal growth apparatus, a growth mask is then formed on the GaN-based semiconductor layer using a SiO₂ film or the like, this substrate is then again placed in the crystal growth apparatus, and subsequently, a GaN-based semiconductor layer is again epitaxially grown using this growth mask.

According to this technique, the dislocation density of the upper-side GaN-based semiconductor layer can be decreased; however, since epitaxial growth is performed twice in this case, the manufacturing cost is unfavorably increased.

Accordingly, a method has been proposed in which after an irregularity-forming process is performed beforehand on a different type substrate, a GaN-based semiconductor is epitaxially grown on this processed substrate (for example, see “Development of high-output UV LED using a LEPS method” Mitsubishi Cable Industries Review, No. 98, October 2001, and Japanese Unexamined Patent Application Publications Nos. 2004-6931 and 2004-6937). This method is schematically shown in FIGS. 46A to 46C. According to this method, first, as shown in FIG. 46A, an irregularity-forming process is performed on one major surface of a c-plane sapphire substrate 101. Reference numerals 101a and 101b indicate a concave portion and a convex portion, respectively. These concave portions 101a and the convex portions 101b extend in the <1-100> direction of the sapphire substrate 101. Next, on this sapphire substrate 101, a GaN-based semiconductor layer 102 is grown through steps shown in FIGS. 46B and 46C. In FIG. 46C, dotted lines indicate growth interfaces formed during the growth. In this epitaxial growth, it is very characteristic that a space 103 is unfavorably formed between the sapphire substrate 101 and the GaN-based semiconductor layer 102 in the concave portion 101a as shown in FIG. 46C. The crystalline defect distribution in the GaN-based semiconductor layer 102 thus grown by this method is schematically shown in FIG. 47. As shown in FIG. 47, in the GaN-based semiconductor layer 102 on the convex portion 101b, threading dislocations 104 are generated from the interface with the upper surface of this convex portion 101b in a direction perpendicular to the interface to form a high defect density region 105, and above the concave portion 101a and between the high defect density regions 105, a low defect density region 106 is formed.

As shown in FIG. 46C, the shape of the GaN-based semiconductor layer 102 filled under the space 103 formed inside the concave portion 101a of the sapphire substrate 101 is a quadrangle; however, the GaN-based semiconductor layer thus filled may have a triangle shape in some cases, and also in this case, the GaN-based semiconductor layer 102 filled in this concave portion 101a may come into contact with the GaN-based semiconductor layer 102 grown in the lateral direction to form the space as is the case of the quadrangle shape described above.

In FIGS. 48A to 48D, growth steps of the GaN-based semiconductor layer 102 are shown for reference in the case in which the extending direction of the concave portions 101a and that of the convex portions 101b are the <11-20> direction orthogonal to the <1-100> direction of the sapphire substrate 101.

In FIGS. 49A to 49F, a growth method different from that described above is shown (for example, see Japanese Unexamined Patent Application Publication No. 2003-318441). By this method, as shown in FIG. 49A, the sapphire substrate 101 treated by an irregularity-forming process is used, and the GaN-based semiconductor layer 102 is formed thereon through the steps shown in FIGS. 49B to 49F. It has been disclosed that by this method, the GaN-based semiconductor layer 102 can be formed without forming spaces between the sapphire substrate 101 and the GaN-based semiconductor layer 102.

Growth methods have also been proposed in which convex portions are formed on a substrate using a material different therefrom, and the growth of a nitride-based III-V compound semiconductor is started from concave portions between the convex portions (for example, see Japanese Unexamined Patent Application Publication No. 2003-324069 and Japanese Patent No. 2830814); however, the above growth manner is apparently different from that of the present invention.

### SUMMARY OF THE INVENTION

According to the related method shown in FIGS. 46A to 46C, the spaces 103 are unfavorably formed between the sapphire substrate 101 and the GaN-based semiconductor layer 102 as described above, and in addition, according to the results of experiments carried out by the inventors of the present invention, it was found that when a light-emitting diode structure is formed by growing GaN-based semiconductor layers on the GaN-based semiconductor layer 102, this light-emitting diode disadvantageously has a low luminous efficiency. The reason for this is believed that since light emitted from an active layer during operation of the light-emitting diode is repeatedly reflected inside the space, the light is absorbed, and as a result, the light extraction efficiency becomes inferior.

On the other hand, by the related growth method shown in FIGS. 49A to 49F, although it has been disclosed that no spaces are formed between the sapphire substrate 101 and the GaN-based semiconductor layer 102, it is believed that the dislocation density of the GaN-based semiconductor layer 102 is difficult to be decreased to a level equivalent to that of the related growth method shown in FIGS. 46A to 46C. Hence, when a light-emitting diode structure is formed by growing GaN-based semiconductor layers on the GaN-based semiconductor layer 102 having a high dislocation density, the dislocation density of the grown GaN-based semiconductor layers is also increased, and as a result, the luminous efficiency is decreased.

Furthermore, in both related growth methods shown in FIGS. 46A to 46C and FIGS. 49A to 49F, dry etching is generally performed on the surface of the sapphire substrate 101 as an irregularity-forming process; however, since the sapphire substrate 101 is not easy to be dry-etched, the etching takes a long time, and in addition, the process accuracy thereof is also low.

Accordingly, it is desirable to provide a light-emitting diode and a manufacturing method thereof, the light-emitting diode having a significantly high luminous efficiency due to significant improvement in light extraction efficiency and improvement in internal quantum efficiency by significant improvement in crystallinities of nitride-based III-V compound semiconductor layers forming a light-emitting diode, being manufactured at a reasonable cost by one epitaxial growth, and using a substrate which can be easily processed by an irregularity-forming process.

In addition, it is also desirable to provide a high-performance light source cell unit, light-emitting diode backlight, light-emitting diode illuminating device, light-emitting diode display, and electronic apparatus, each using the light-emitting diode as described above.

The light-emitting diode, the manufacturing method thereof, and the various electronic devices and apparatuses using the above light-emitting diode described above will become apparent from the following description with reference to the accompanying drawings.

In order to solve the problems described above, the inventors of the present invention carried out intensive research, and the results obtained therefrom are as described below.

According to the knowledge of the inventors of the present invention, in the case in which nitride-based III-V compound semiconductor layers forming a light-emitting diode structure are grown, when a substrate provided with convex portions on one major surface, which are formed of a different material from the substrate, that is, a concavo-convex substrate, is used, a first nitride-based III-V compound semiconductor layer is first grown in a concave portion on the substrate through the state of a triangle cross-sectional shape using the bottom surface of the concave portion as the base, and a second nitride-based III-V compound semiconductor layer is then grown on the substrate from the first nitride-based III-V compound semiconductor layer in a lateral direction, spaces can be prevented from being formed among the substrate, the first nitride-based III-V compound semiconductor layer, and the second nitride-based III-V compound semiconductor layer. In addition, since the crystallinity of the second nitride-based III-V compound semiconductor layer can be made superior, the crystallinities of a third nitride-based III-V compound semiconductor layer, an active layer, and a fourth nitride-based III-V compound semiconductor layer, which are sequentially grown on the second nitride-based III-V compound semiconductor layer, can also be significantly improved.

In addition, through intensive research carried out by the inventors of the present invention, it was found that when the substrate as described above is used, by appropriately selecting a material for the convex portions, the far-field pattern (intensity distribution at a far-field point) of a light-emitting diode can be controlled without using an optical component such as a lens. In this case, appropriate selection of a material for the convex portions means that the ratio between the radiant flux from the upper surface and that from the side surface of a light-emitting diode is changed, and the far-field pattern can be controlled while the decrease in luminous efficiency is suppressed which is caused by attenuation of light emitted from the active layer due to the total reflection thereof in semiconductor layers forming the light-emitting diode structure. Light-emitting diodes are used in various application fields, such as displays, backlights, and illuminating devices, and since desired light emission intensity distribution varies depending on applications, it is very significant to be able to control the far-field pattern as described above. Hereinafter, the particular findings obtained by the inventors of the present invention will be schematically described.

The luminous efficiency of the light-emitting diode is determined by the internal quantum efficiency and the light extraction efficiency. The light extraction efficiency indicates the ratio of light beams escaping outside the light-emitting diode to light beams emitted from the active layer thereof, and improvement in light extraction efficiency is particularly important to improve the brightness of the light-emitting diode. In general, since light beams emitted from the active layer are difficult to escape out of the semiconductor layers forming the light-emitting diode due to the total reflection, while traveling to and from in the semiconductor layers, the light beams are attenuated. Inside the semiconductor layers, although light beams in an escape cone can escape outside, many light beams which are not in the escape cone are attenuated, and as a result, the light extraction efficiency is decreased.

In the light-emitting diode in which the nitride-based III-V compound semiconductor layer forming a light-emitting diode structure is grown using the above concavo-convex substrate, by its concavo-convex structure, the attenuation caused by the total refection inside the nitride-based III-V compound semiconductor layer can be suppressed, and the number of light beams entering the escape cone can be increased. That is, when the cross-sectional shape of the nitride-based III-V compound semiconductor layer forming a light-emitting diode is an ideal rectangular shape, light beams which do not enter the escape cone continue to be reflected at the interface between this nitride-based III-V compound semiconductor layer and the external medium, and as a result, the light beams are attenuated. However, on the other hand, as shown in FIG. 1, in a light-emitting diode in which nitride-based III-V compound semiconductor layers (an n-type nitride-based III-V compound semiconductor layer 3, an active layer 4, and a p-type nitride-based III-V compound semiconductor layer 5) forming a light-emitting diode structure are grown on a concavo-convex substrate made of a substrate 1 and convex portions 2 provided on one major surface thereof, since a concavo-convex structure is present inside the nitride-based III-V compound semiconductor layer, the reflection angle of light beams emitted from the active layer 4 can be changed, and the number of light beams entering the escape cone is increased; hence, the light extraction efficiency can be improved.

In general, the far-field pattern of light emitted from an upper surface of a light-emitting diode as shown in FIG. 2 in which semiconductor layers forming a light-emitting diode structure each have a parallel plate shape exhibits an intensity distribution called a Lambertian distribution as shown in FIG. 3. The Lambertian distribution is a distribution in which a light-condensing property is high in a vertex direction of a light-emitting diode, and in general, when light is to be scattered, light scattering is performed using an optical component in combination with a light-emitting diode. On the other hand, the far-field pattern of light emitted from a side surface is a high light-scattering distribution having peaks in a wide angle range; however, since the area of the side surface is not large as compared to that of the upper surface, the total light emission distribution from all the surfaces has a high light-condensing property.

In the light-emitting diode shown in FIG. 2, since interference occurs between a light beam A and a light beam B which are emitted from the active layer 4 and are then emitted outside the substrate 1 through different paths, the light extraction efficiency and the far-field pattern are changed. The changes in light extraction efficiency and far-field pattern caused by the interference phenomenon are determined by the phase difference between the light beams A and B, and in general, this phase difference is determined by the difference in optical length between the light beams A and B and the phase shift of the light beam B at a reflection surface. When many directions which enhance the light intensity by the interference are made present in the escape cone, the light extraction efficiency can be improved.

By a distance D from a luminous point to a reflection surface shown in FIG. 1, the total radiant flux and the shape of the far-field pattern of the light-emitting diode are changed. Prior to a step of optimizing a medium of the above convex portions of the concavo-convex substrate, it is particularly important to determine the distance D. After the distance D is determined, the medium of the convex portions 2 is determined so as to obtain a desired shape of the far-field pattern. By the change in refractive index of the medium of the convex portions 2, the ratio in light quantity between light emission from the upper surface and that from the side surface of the light-emitting diode is changed. As shown in FIGS. 4A and 4B, the case will be discussed in which the convex portions 2 on the substrate 1 each have a trapezoid cross-sectional shape and a hexagonal planar shape and are two-dimensionally arranged to form a honeycomb shape. FIG. 4A is a cross-sectional view, FIG. 4B is a plan view when the concavo-convex structure of this substrate 1 is viewed from the substrate 1 side, and FIG. 4A is a cross-sectional view taken along the line IVA-IVA shown in FIG. 4B. The width of the convex portion 2, the height of the convex portion 2, the width of a concave portion 6 between the convex portions 2, and the angle between the major surface of the substrate 1 and the side surface of the convex portion 2 are represented by Wₜ, d, W_{g}, and θ, respectively. FIG. 5 is a graph showing the results obtained by calculation using an electromagnetic optical simulation in which the change in light extraction magnification (light extraction efficiency normalized by that of a light-emitting diode having no concavo-convex structure and a distance D of 1.109 λn (hereinafter, the light extraction magnification indicates the same as described above)) and the change in side-surface luminous ratio (ratio of light quantity from the side surface to the total light quantity (hereinafter, it indicates the same as described above)) are shown with the change in distance D between the luminous point and the reflection surface. However, in this case, the n-type nitride-based III-V compound semiconductor layer 3, the active layer 4, and the p-type nitride-based III-V compound semiconductor layer 5 are all formed from GaN, the substrate 1 is a sapphire substrate, and the width Wₜ, the width of an upper surface of the convex portion 2, the height d, the width W_{g}, and the refractive index n of a material for the convex portion 2 are set to 4.0 μm, 3.272 μm, 1.0 μm, 1.5 μm, and 1.46, respectively. Conditions of an electromagnetic optical simulation which will be performed hereinafter are similar to those described above, as long as materials to be used have common properties, that is, in other words, as long as particular materials or substances are not used. As can be seen from FIG. 5, when the light extraction efficiency is maximized, the side-surface luminous ratio is approximately minimized, and hence the light-scattering property is low. FIG. 6 is a graph showing the calculation results of the change in far-field pattern with the side-surface luminous ratio, which are obtained when a light-emitting wavelength is 530 nm, and the distance D from the luminous point to the reflection surface is 0.7 λn. As apparent from FIG. 6, in particular, when the side-surface luminous ratio is 0.6, light is not only condensed in the direction over the light-emitting diode, and a high light-scattering property is obtained. Hence, it is understood that in order to enhance the light-scattering property, the light quantity from the side surface is preferably large.

In the light-emitting diode having a concavo-convex structure as shown in FIGS. 1, 4A, and 4B, by changing the refractive index n of the convex portion 2, the light extraction efficiency and the far-field pattern of the light-emitting diode can be controlled. FIGS. 7A and 7B show the results of the electromagnetic optical simulation, in which when the light-emitting wavelength is 530 nm, and the distances D from the luminous point to the reflection surface are 0.93 and 1.11 λn, respectively, the change in light extraction magnification and that in side-surface luminous ratio are shown with the change in refractive index of the convex portion 2. As can be seen from FIGS. 7A and 7B, when the refractive index of the convex portion 2 is approximately 2.0, the light extraction efficiency is maximized, and the side-surface luminous ratio is also increased. In order to improve the light extraction efficiency, the refractive index of the convex portion 2 is set in the range of 1.7 to 2.1 or is preferably set to approximately 2.0. In addition, in order to improve the light-scattering property, the refractive index of the convex portion 2 is set in the range of 1.7 to 2.2 or is preferably set to approximately 2.0.

Also in a light-emitting diode shown in FIG. 8 which is substantially the same as the light-emitting diode shown in FIG. 1 except that the substrate 1 is removed therefrom while the convex portions 2 are allowed to remain, as is the case described above, the light extraction efficiency and the far-field pattern of the light-emitting diode can be controlled by changing the refractive index n of the convex portion 2. FIG. 9 shows the results of the electromagnetic optical simulation in which when the light-emitting wavelength is 530 nm, and the distance D from the luminous point to the reflection surface is 1.11 λn, the change in light extraction magnification and that in side-surface luminous ratio are shown with the change in refractive index of the convex portion 2. As apparent from FIG. 9, when the refractive index of the convex portion 2 is approximately 1.55, the light extraction efficiency is maximized, and the side-surface luminous ratio is high. In order to improve the light extraction efficiency, the refractive index of the convex portion 2 is set in the range of 1.0 to 1.8 or is preferably set to approximately 1.55. In addition, in order to improve the light-scattering property, the refractive index of the convex portion 2 is set in the range of 1.0 to 2.3 or is preferably set in the range of approximately 1.3 to 1.85.

The most preferable range of the refractive index of the convex portion 2 described above is effective regardless of the angle θ between the major surface of the substrate 1 and the side surface of the convex portion 2, the width Wₜ of the convex portion 2, the height d thereof, the width W_{g} of the concave portion 6, the plan shape of the convex portion 2, the two-dimensional arrangement pattern thereof, the light-emitting wavelength λ, and the like.

In addition, when a ferroelectric substance is selected as the medium of the convex portion 2, by applying an external electric field to the convex portion 2, the refractive index of the convex portion 2 can be changed by the electro-optical effect. In this case, as is the case described above, since the side-surface luminous ratio and the light extraction efficiency are changed, the far-field pattern can be continuously changed by electric field application.

The present invention has been conceived based on the findings described above by the inventors of the present invention.

That is, in order to solve the problems described above, according to a first embodiment of the present invention, there is provided a method for manufacturing a light-emitting diode, comprising the steps of: preparing a substrate provided with convex portions on one major surface, the convex portions being formed from a dielectric substance which is different from the substrate and which has a refractive index of 1.7 to 2.2; growing a first nitride-based III-V compound semiconductor layer in a concave portion on the substrate through the state of a triangle cross-sectional shape using the bottom surface of the concave portion as the base; growing a second nitride-based III-V compound semiconductor layer on the substrate from the first nitride-based III-V compound semiconductor layer in a lateral direction; and sequentially growing, on the second nitride-based III-V compound semiconductor layer, a first conductive type third nitride-based III-V compound semiconductor layer, an active layer, and a second conductive type fourth nitride-based III-V compound semiconductor layer.

The first nitride-based III-V compound semiconductor layer and the second nitride-based III-V compound semiconductor layer may have any conductive type, that is, any one of a p-type, an n-type, and an i-type, and may have or may have not the same conductive type. In addition, in the first nitride-based III-V compound semiconductor layer or the second nitride-based III-V compound semiconductor layer, at least two portions having different conductive types may be simultaneously present.

Typically, in the growth of the first nitride-based III-V compound semiconductor layer, when dislocation is generated from the interface with the bottom surface of the concave portion on the substrate in a direction perpendicular to one major surface thereof and then extends to the inclined surface of the first nitride-based III-V compound semiconductor layer in the state of the above triangle cross-sectional shape or to the vicinity of the inclined surface, the dislocation is bent in a direction parallel to the above major surface so as to be apart from the triangle shape portion. In this case, the triangle cross-sectional shape or the triangle of the triangle shape portion does not only indicate a precise triangle shape but also includes a shape approximately regarded as a triangle, such as a triangle having a round apex (hereinafter, the triangle indicates the same as described above). In addition, preferably, at the early growth stage of the first nitride-based III-V compound semiconductor layer, minute nuclei are generated from the bottom surface of the concave portion on the substrate, and during the process including the growth and coalescence of the minute nuclei, dislocations generated from the interfaces with the bottom surfaces of the concave portions on the substrate in a direction perpendicular to one major surface thereof are repeatedly bent in a direction parallel to the major surface described above. Accordingly, when the first nitride-based III-V compound semiconductor layer is grown, the number of dislocations propagated to the upper side can be decreased.

Typically, the convex portions and the concave portions are alternately and periodically formed on one major surface of the substrate. In this case, the interval of the convex portions and that of the concave portions are each preferably 3 to 6 μm; however, the interval is not limited thereto. In addition, the ratio of the length of the bottom surface of the convex portion to the length of the bottom surface of the concave portion is preferably in the range of 0.5 to 3 and most preferably approximately 0.5; however, the ratio is not limited thereto. The height of the convex portion from the major surface of the substrate is preferably 0.3 μm or more and more preferably 1 μm or more. This convex portion preferably has at least one inclined surface with respect to the major surface of the substrate, and when the angle between this side surface and the major surface of the substrate is represented by θ, in order to improve the light extraction efficiency, for example, 30°<θ<80° preferably holds, and θ is most preferably approximately 40°; however, the angle θ is not limited thereto. The convex portion may have various cross-sectional shapes, and the side surface thereof may also be a curved surface as well as a flat surface; for example, an n-polygon (in which n is an integer of 3 or more), such as a triangle, a quadrangle, a pentagon, or a hexagon; an n-polygon as mentioned above having at least one truncated or rounded apex; a circle; or an oval may be mentioned. Among those mentioned above, a shape having one apex at a highest position from the major surface of the substrate is preferable, and in particular, a triangle or a triangle having a truncated or rounded apex is most preferable. The cross-section of the concave portion may also have various shapes, and for example, an n-polygon (in which n is an integer of 3 or more), such as a triangle, a quadrangle, a pentagon, or a hexagon; an n-polygon as mentioned above having at least one truncated or rounded apex; a circle; or an oval may be mentioned. In order to improve the light extraction efficiency, the cross-section of this concave portion preferably has an inverted trapezoid. In this case, the inverted trapezoid does not only indicate a precise inverted trapezoid but also includes a shape approximately regarded as an inverted trapezoid (hereinafter, the inverted trapezoid indicates the same as described above). In this case, in order to minimize the dislocation density of the second nitride-based III-V compound semiconductor layer, when the depth of the concave portion (same as the height of the convex portion), the width of the bottom surface of the concave portion, and the angle between one major surface of the substrate and the inclined surface of the first nitride-based III-V compound semiconductor layer in the state of a triangle cross-sectional shape are represented by d, W_{g}, and α, respectively, d, W_{g}, and α are preferably determined so that 2 d≧Wg×tan α holds. Since the angle α is generally constant, d and W_{g} are determined to satisfy the above equation. When the depth d is excessively large, since a raw material gas is not sufficiently supplied inside the concave portion, the growth of the first nitride-based III-V compound semiconductor layer from the bottom surface of the concave portion may have a problem, and on the other hand, when the depth d is excessively small, in addition to the concave portion on the substrate, the first nitride-based III-V compound semiconductor layer is also grown on the convex portions located at the two sides of the above concave portion. In order to prevent the above problems, the depth d is generally determined in the range of 0.5 to 5 μm and is typically set to 1.0±0.2 μm; however, the depth d is not limited thereto. The width Wg is generally 0.5 to 5 μm and is generally set in the range of 2±0.5 μm; however, the width Wg is not limited thereto. In addition, the width of the upper surface of the convex portion is 0 when the cross-sectional shape thereof is a triangle; however, when the cross-sectional shape of the convex portion is a trapezoid, since this convex portion is a region to be used for the lateral growth of the second nitride-based III-V compound semiconductor layer, an area having a low dislocation density can be increased as the width of the upper surface of the convex portion is increased. When the cross-sectional shape of the convex portion is a trapezoid, the width Wₜ is generally 1 to 1,000 μm, such as in the range of 4±2 μm; however, the width Wₜ is not limited thereto.

The convex portions or the concave portions may be formed in a stripe pattern to extend in one direction on the substrate or may be formed in a stripe pattern to extend in a first direction and a second direction on the substrate to intersect each other. In the latter case, the convex portions may have a two-dimensional pattern including an n-polygon (in which n is an integer of 3 or more), such as a triangle, a quadrangle, a pentagon, or a hexagon; an n-polygon as mentioned above having at least one truncated or rounded apex; a circle; an oval; or a dot. As one preferable example, the convex portions each have a hexagonal planar shape and are two-dimensionally arranged to form a honeycomb pattern, and the concave portions are formed so as to surround the convex portions. Accordingly, light emitted from the active layer can be efficiency extracted in all the directions of 36020 . Alternatively, the concave portions each have a hexagonal planar shape and are two-dimensionally arranged to form a honeycomb pattern, and the convex portions may be formed to surround the concave portions. When the concave portions on the substrate have a stripe pattern, the concave portions may extend, for example, in the <1-100> direction of the first nitride-based III-V compound semiconductor layer or, when a sapphire substrate is used as the substrate, the concave portions may extend in the <11-20> direction of this sapphire substrate. The shape of the convex portion is, for example, an n-polygonal pyramid (in which n is an integer of 3 or more), such as a triangular pyramid, a quadrangular pyramid, a pentagonal pyramid, or a hexagonal pyramid; an n-polygonal pyramid as mentioned above having at least one truncated or rounded apex; an circular cone; or an oval cone.

As the dielectric substance forming the convex portions, any material which has a refractive index of 1.7 to 2.2 and which preferably does not remarkably absorb light having a light-emitting wavelength may be basically used, and for example, an oxide, a nitride, an oxynitride, or a fluoride may be mentioned. Whenever necessary, the convex portion may be formed by mixing at least two types of dielectric substances or by using a laminated film composed of at least two types of dielectric substances. The particular examples of this dielectric substance are shown below. However, besides the dielectric substances having the following stoichiometric compositions, dielectric substances having non-stoichiometric compositions slightly deviated therefrom may also be used.

| | | Wavelength |
|---|---|---|
| Material | Refractive Index | (nm) |
| Cerium oxide (CeO₂) | 2.20 | 550 |
| Hafnium oxide (HfO₂) | 1.95 | 550 |
| Tantalum pentaoxide (Ta₂O₅) | 2.16 | 550 |
| Yttrium oxide (Y₂O₃) | 1.87 | 550 |
| Zinc oxide (ZnO) | 2.10 | 550 |
| Zirconium oxide (ZrO₂) | 2.05 | 550 |
| Rhombic sulfur | 2.01 | |
| Lithium tantalate (LiTaO₃) | 2.21 | 530 |
| Lithium niobate (LiNbO₃) | 2.32 | 530 |
| | (ordinary ray) | |
| Lithium niobate (LiNbO₃) | 2.24 | 530 |
| | (extraordinary ray) | |
| Aluminum oxynitride (AlON) | 1.79 | 530 |
| Silicon monoxide (SiO) | 2.01 | 530 |
| Silicon nitride (Si₃N₄) | 2.04 | 530 |
| Aluminum oxide (Al₂O₃) | 1.77 | 530 |
| Beryllium oxide (BeO) | 1.72 | 530 |
| Magnesium oxide (MgO) | 1.74 | 530 |

In order to improve the light extraction efficiency of the light-emitting diode, the refractive index of the dielectric substance forming the convex portions is preferably in the range of 1.7 to 2.1 and most preferably approximately 2.0 (such as 1.9 to 2.1), and in order to improve the light-scattering property, the refractive index is most preferably approximately 2.0 (such as 1.9 to 2.1).

In order to grow the first nitride-based III-V compound semiconductor layer only in the convex portion on the substrate, for example, at least the surface of the convex portion is preferably formed of an amorphous layer. The reason for this is to use a phenomenon in which nuclear formation is not likely to occur on an amorphous layer during the growth.

In addition, since threading dislocations are concentrated at coalescent portions of the second nitride-based III-V compound semiconductor layers located above the convex portions, when dislocation-propagation inhibitory parts made of an insulating material, a void, or the like are formed beforehand on the convex portions so as to inhibit the propagation of dislocations in a direction parallel to one major surface of the substrate, the propagation of dislocations to the surface of the second nitride-based III-V compound semiconductor layer is inhibited, thereby preventing the formation of threading dislocations.

On the third nitride-based III-V compound semiconductor layer, a first conductive type electrode is formed so as to be electrically connected thereto. In a manner similar to that described above, on the fourth nitride-based III-V compound semiconductor layer, a second conductive type electrode is formed so as to be electrically connected thereto.

Various materials may be used for the substrate. As the substrate formed from a material different from the nitride-based III-V compound semiconductor, for example, in particular, there may be used a substrate formed from sapphire (c-plane, a-plane, r-plane, a plane offset from the aforementioned plane, or the like), SiC (6H, 4H, 3C, or the like), Si, ZnS, ZnO, LiMgO, GaAs, spinel (MgAl₂O₄, or ScAlMgO₄), garnet, CrN (such as CrN(111)), or the like. A hexagonal substrate or a cubic substrate made of aforementioned materials is preferably used, and in particular, a hexagonal substrate is more preferably used. As the substrate, a substrate made of a nitride-based III-V compound semiconductor (GaN, AlGaInN, AlN, GaInN, or the like) may also be used. Alternatively, as the substrate, a nitride-based III-V compound semiconductor layer may be used which is grown on a base plate formed of a material different therefrom, and the convex portions may then be formed on this nitride-based III-V compound semiconductor layer.

In addition, for example, when a layer, such as a nitride-based III-V compound semiconductor layer, grown on a base plate is used as the substrate, as a material for the convex portions, a material different from that for a layer in direct contact therewith is used.

In the case described above, the substrate is not removed and is allowed to remain in a light-emitting diode which is finally manufactured as a product.

The first to the fourth nitride-based III-V compound semiconductor layers and the nitride-based III-V compound semiconductor layer forming the active layer are most commonly represented by AlₓB_{y}Ga_{1-x-y-z}In_{z}AsᵤN₁₋ᵤ₋ᵥPᵥ (where 0≦x≦1, 0≦y≦1, 0≦z≦1, 0≦u≦1, 0≦v≦1, 0≦x+y+z<1, and 0≦u+v<1), in particular, represented by AlₓB_{y}Ga_{1-x-y-z}In_{z}N (where 0≦x≦1, 0≦y≦1, 0≦z≦1, and 0≦x+y+z<1), and typically, represented by AlₓGa_{1-x-z}In_{z}N (where 0≦x≦1 and 0≦z≦1). As a concrete example, for example, GaN, InN, AlN, AlGaN, InGaN, or AlGaInN may be mentioned. Since an effect to facilitate the bending of dislocations is obtained, for example, when B, Cr, or the like is contained in GaN, the first to the fifth nitride-based III-V compound semiconductor layers and the nitride-based III-V compound semiconductor layer forming the active layer may be formed of BGaN, GaN:B obtained from GaN doped with B, GaN:Cr obtained from GaN doped with Cr, or the like. In particular, as the first nitride-based III-V compound semiconductor layer which is first formed in the convex portion on the substrate, GaN, InₓGa₁₋ₓN (0<x<0.5), AlₓGa₁₋ₓN (0<x<0.5), or AlₓIn_{y}Ga_{1-x-y}N (0<x<0.5, 0<y<0.2) is preferably used. The first conductive type may be either an n-type or a p-type, and in accordance therewith, the second conductive type is a p-type or an n-type. In addition, as a so-called low-temperature buffer layer which is first formed on the substrate, a GaN buffer layer, an AlN buffer layer, an AlGaN buffer layer, or the like may be generally used, and in addition, a buffer layer formed by doping the aforementioned layer with Cr, a CrN buffer layer, or the like may also be used.

The thickness of the second nitride-based III-V compound semiconductor layer is appropriately determined and is typically approximately several micrometers or less; however, depending on applications or the like, the thickness may be larger than that described above, such as approximately several tens of micrometers to 300 μm.

As a method for growing the first to the fourth nitride-based III-V compound semiconductor layers and the nitride-based III-V compound semiconductor layer forming the active layer, for example, there may be used various epitaxial growth methods, such as metal organic chemical vapor deposition (MOCVD), hydride vapor phase epitaxial growth or halide vapor phase epitaxial growth (HVPE), and molecular beam epitaxial growth (MBE).

In accordance with a second embodiment of the present invention, there is provide a light-emitting diode comprising: a substrate provided with convex portions on one major surface, the convex portions being composed of a dielectric substance which is different from the substrate and which has a refractive index of 1.7 to 2.2; a fifth nitride-based III-V compound semiconductor layer grown on the substrate without forming a space in a concave portion on the substrate; and a first conductive type third nitride-based III-V compound semiconductor layer, an active layer, and a second conductive type fourth nitride-based III-V compound semiconductor layer, which are provided on the fifth nitride-based III-V compound semiconductor layer. In the light-emitting diode described above, in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

In the second embodiment and the following fourth to sixteenth embodiments of the present invention, the fifth nitride-based III-V compound semiconductor layer corresponds to the first and the second nitride-based III-V compound semiconductor layers according to the first embodiment of the present invention.

To the second and the following third to the sixteenth embodiments of the present invention, the description relating to the first embodiment of the present invention can also be applied, as long as materials to be used have common properties, that is, in other words, as long as particular materials or substances are not used.

In accordance with a third embodiment of the present invention, there is provide a method for manufacturing a light-emitting diode, comprising the steps of: preparing a substrate provided with convex portions on one major surface, the convex portions being formed from a dielectric substance which is different from the substrate and which has a refractive index of 1.0 to 2.3; growing a first nitride-based III-V compound semiconductor layer in a concave portion on the substrate through the state of a triangle cross-sectional shape using the bottom surface of the concave portion as the base; growing a second nitride-based III-V compound semiconductor layer on the substrate from the first nitride-based III-V compound semiconductor layer in a lateral direction; sequentially growing, on the second nitride-based III-V compound semiconductor layer, a first conductive type third nitride-based III-V compound semiconductor layer, an active layer, and a second conductive type fourth nitride-based III-V compound semiconductor layer; and removing the substrate.

In accordance with a fourth embodiment of the present invention, there is provided a light-emitting diode comprising: a fifth nitride-based III-V compound semiconductor layer; and a first conductive type third nitride-based III-V compound semiconductor layer, an active layer, and a second conductive type fourth nitride-based III-V compound semiconductor layer, which are provided on the fifth nitride-based III-V compound semiconductor layer. In the light-emitting diode described above, in one major surface of the fifth nitride-based III-V compound semiconductor layer located at a side opposite to that of the active layer, convex portions composed of a dielectric substance having a refractive index of 1.0 to 2.3 are buried, and in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

In this embodiment, the structure in which the convex portions composed of a dielectric substance having a refractive index of 1.0 to 2.3 are buried in one major surface of the fifth nitride-based III-V compound semiconductor layer located at a side opposite to the active layer is the same structure in the third embodiment of the present invention which is obtained by removing the substrate while the convex portions are allowed to remain.

In the third and the fourth embodiments of the present invention, as the dielectric substance forming the convex portions, any material may be basically used as long as it has a refractive index of 1.0 to 2.3 and preferably does not remarkably absorb light of a light-emitting wavelength, and in particular, besides the materials described in the first embodiment of the present invention by way of example, the following dielectric substances may also be mentioned. The convex portions may be formed by mixing at least two types of dielectric substances or may be formed from a laminated film containing at least two types of dielectric substances. However, besides the dielectric substances having the following stoichiometric compositions, dielectric substances having non-stoichiometric compositions slightly deviated therefrom may also be used. As the dielectric substance forming the convex portions, air (refractive index: approximately 1.0) may also be used.

| | | Wavelength |
|---|---|---|
| Material | Refractive Index | (nm) |
| Silicon dioxide (SiO₂) | 1.46 | 530 |
| Lithium fluoride (LiF) | 1.39 | 530 |
| Calcium fluoride (CaF₂) | 1.44 | 530 |
| Magnesium fluoride (MgF₂) | 1.38 | 530 |
| Sodium fluoride (NaF) | 1.33 | 530 |
| Aluminum fluoride (AlF₃) | 1.38 | 550 |
| Cerium fluoride (CeF₃) | 1.63 | 550 |
| Lanthanum fluoride (LaF₃) | 1.59 | 550 |
| Neodymium fluoride (NdF₃) | 1.61 | 550 |

In order to improve the light extraction efficiency of the light-emitting diode, the refractive index of the dielectric substance forming the convex portions is preferably in the range of 1.0 to 1.8 and is, in particular, more preferably approximately 1.55, and in order to improve the light-scattering property, the refractive index is preferably in the range of 1.3 to 1.85.

In accordance with a fifth embodiment of the present invention, there is provided a light source cell unit comprising: a plurality of arranged cells, each having at least one red light-emitting diode, at least one green light-emitting diode, and at least one blue light-emitting diode, in which at least one light-emitting diode of the red light-emitting diode, the green light-emitting diode, and the blue light-emitting diode includes, a substrate provided with convex portions on one major surface, the convex portions being composed of a dielectric substance which is different from the substrate and which has a refractive index of 1.7 to 2.2; a fifth nitride-based III-V compound semiconductor layer grown on the substrate without forming a space in a concave portion on the substrate; and a first conductive type third nitride-based III-V compound semiconductor layer, an active layer, and a second conductive type fourth nitride-based III-V compound semiconductor layer, which are provided on the fifth nitride-based III-V compound semiconductor layer. In addition, in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

In accordance with a sixth embodiment of the present invention, there is provided a light source cell unit comprising: a plurality of arranged cells, each having at least one red light-emitting diode, at least one green light-emitting diode, and at least one blue light-emitting diode, in which at least one light-emitting diode of the red light-emitting diode, the green light-emitting diode, and the blue light-emitting diode includes, a fifth nitride-based III-V compound semiconductor layer; and a first conductive type third nitride-based III-V compound semiconductor layer, an active layer, and a second conductive type fourth nitride-based III-V compound semiconductor layer, which are provided on the fifth nitride-based III-V compound semiconductor layer. In the light source cell unit described above, in one major surface of the fifth nitride-based III-V compound semiconductor layer located at a side opposite to that of the active layer, convex portions composed of a dielectric substance having a refractive index of 1.0 to 2.3 are buried, and in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

In accordance with a seventh embodiment of the present invention, there is provided a light-emitting diode backlight comprising: a plurality of red light-emitting diodes, a plurality of green light-emitting diodes, and a plurality of blue light-emitting diodes, the light-emitting diodes being arranged; wherein at least one light-emitting diode of the red light-emitting diodes, the green light-emitting diodes, and the blue light-emitting diodes includes, a substrate provided with convex portions on one major surface, the convex portions being composed of a dielectric substance which is different from the substrate and which has a refractive index of 1.7 to 2.2; a fifth nitride-based III-V compound semiconductor layer grown on the substrate without forming a space in a concave portion on the substrate; and a first conductive type third nitride-based III-V compound semiconductor layer, an active layer, and a second conductive type fourth nitride-based III-V compound semiconductor layer, which are provided on the fifth nitride-based III-V compound semiconductor layer; wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

In accordance with an eighth embodiment of the present invention, there is provided a light-emitting diode backlight comprising: a plurality of red light-emitting diodes, a plurality of green light-emitting diodes, and a plurality of blue light-emitting diodes, the light-emitting diodes being arranged; wherein at least one light-emitting diode of the red light-emitting diodes, the green light-emitting diodes, and the blue light-emitting diodes includes, a fifth nitride-based III-V compound semiconductor layer; and a first conductive type third nitride-based III-V compound semiconductor layer, an active layer, and a second conductive type fourth nitride-based III-V compound semiconductor layer, which are provided on the fifth nitride-based III-V compound semiconductor layer; wherein in one major surface of the fifth nitride-based III-V compound semiconductor layer located at a side opposite to that of the active layer, convex portions composed of a dielectric substance having a refractive index of 1.0 to 2.3 are buried, and in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

In accordance with a ninth embodiment of the present invention, there is provided a light-emitting diode illuminating device comprising: a plurality of red light-emitting diodes, a plurality of green light-emitting diodes, and a plurality of blue light-emitting diodes, the light-emitting diodes being arranged; wherein at least one light-emitting diode of the red light-emitting diodes, the green light-emitting diodes, and the blue light-emitting diodes includes, a substrate provided with convex portions on one major surface, the convex portions being composed of a dielectric substance which is different from the substrate and which has a refractive index of 1.7 to 2.2; a fifth nitride-based III-V compound semiconductor layer grown on the substrate without forming a space in a concave portion on the substrate; and a first conductive type third nitride-based III-V compound semiconductor layer, an active layer, and a second conductive type fourth nitride-based III-V compound semiconductor layer, which are provided on the fifth nitride-based III-V compound semiconductor layer; wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

In accordance with a tenth embodiment of the present invention, there is provided a light-emitting diode illuminating device comprising: a plurality of red light-emitting diodes, a plurality of green light-emitting diodes, and a plurality of blue light-emitting diodes, the light-emitting diodes being arranged; wherein at least one light-emitting diode of the red light-emitting diodes, the green light-emitting diodes, and the blue light-emitting diodes includes, a fifth nitride-based III-V compound semiconductor layer; and a first conductive type third nitride-based III-V compound semiconductor layer, an active layer, and a second conductive type fourth nitride-based III-V compound semiconductor layer, which are provided on the fifth nitride-based III-V compound semiconductor layer; wherein in one major surface of the fifth nitride-based III-V compound semiconductor layer located at a side opposite to that of the active layer, convex portions composed of a dielectric substance having a refractive index of 1.0 to 2.3 are buried, and in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

In accordance with an eleventh embodiment of the present invention, there is provided a light-emitting diode display comprising: a plurality of red light-emitting diodes, a plurality of green light-emitting diodes, and a plurality of blue light-emitting diodes, the light-emitting diodes being arranged; wherein at least one light-emitting diode of the red light-emitting diodes, the green light-emitting diodes, and the blue light-emitting diodes includes, a substrate provided with convex portions on one major surface, the convex portions being composed of a dielectric substance which is different from the substrate and which has a refractive index of 1.7 to 2.2; a fifth nitride-based III-V compound semiconductor layer grown on the substrate without forming a space in a concave portion on the substrate; and a first conductive type third nitride-based III-V compound semiconductor layer, an active layer, and a second conductive type fourth nitride-based III-V compound semiconductor layer, which are provided on the fifth nitride-based III-V compound semiconductor layer; wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

In accordance with a twelfth embodiment of the present invention, there is provided a light-emitting diode display comprising: a plurality of red light-emitting diodes, a plurality of green light-emitting diodes, and a plurality of blue light-emitting diodes, the light-emitting diodes being arranged; wherein at least one light-emitting diode of the red light-emitting diodes, the green light-emitting diodes, and the blue light-emitting diodes includes, a fifth nitride-based III-V compound semiconductor layer; and a first conductive type third nitride-based III-V compound semiconductor layer, an active layer, and a second conductive type fourth nitride-based III-V compound semiconductor layer, which are provided on the fifth nitride-based III-V compound semiconductor layer; wherein in one major surface of the fifth nitride-based III-V compound semiconductor layer located at a side opposite to that of the active layer, convex portions composed of a dielectric substance having a refractive index of 1.0 to 2.3 are buried, and in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

According to the fifth to the twelfth embodiments of the present invention, as the red light-emitting diode, for example, a diode using an AlGaInP-based semiconductor may also be used.

In accordance with a thirteenth embodiment of the present invention, there is provided an electronic apparatus comprising: at least one light-emitting diode; wherein said at least one light-emitting diode includes, a substrate provided with convex portions on one major surface, the convex portions being composed of a dielectric substance which is different from the substrate and which has a refractive index of 1.7 to 2.2; a fifth nitride-based III-V compound semiconductor layer grown on the substrate without forming a space in a concave portion on the substrate; and a first conductive type third nitride-based III-V compound semiconductor layer, an active layer, and a second conductive type fourth nitride-based III-V compound semiconductor layer, which are provided on the fifth nitride-based III-V compound semiconductor layer; wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

In accordance with a fourteenth embodiment of the present invention, there is provided an electronic apparatus comprising: at least one light-emitting diode; wherein said at least one light-emitting diode includes, a fifth nitride-based III-V compound semiconductor layer; and a first conductive type third nitride-based III-V compound semiconductor layer, an active layer, and a second conductive type fourth nitride-based III-V compound semiconductor layer, which are provided on the fifth nitride-based III-V compound semiconductor layer; wherein in one major surface of the fifth nitride-based III-V compound semiconductor layer located at a side opposite to that of the active layer, convex portions composed of a dielectric substance having a refractive index of 1.0 to 2.3 are buried, and in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

In the thirteenth and the fourteenth embodiments of the present invention, the electronic apparatus includes light-emitting diode backlights (such as a backlight for liquid crystal displays), light-emitting diode illuminating devices (besides interior and exterior illuminating devices, such as head lights for automobiles, motorcycles, and the like, and flash lamps for cameras), and light-emitting diode displays, and also includes projectors, rear projection televisions, grating light valves, and the like, which use the light-emitting diode as a light source. In general, an apparatus including at least one light-emitting diode for display, illumination, optical communication, optical transmission, and the like may be basically regarded as the electronic apparatus, and portable and stationary type apparatuses are also regarded as the electronic apparatuses. Besides the apparatuses mentioned above, as concrete examples, there may be mentioned by way of example a mobile phone, a mobile apparatus, a robot, a personal computer, an in-car apparatus, various home electric appliances, light-emitting diode optical communication device, light-emitting diode light transmission device, and a portable security device such as an electronic key. In addition, in the electronic apparatus, an apparatus containing at least two types of light-emitting diodes is also included which emit at least two types of light having different wavelength regions from each other, which may be selected from a far infrared wavelength region, an infrared wavelength region, a red wavelength region, a yellow wavelength region, a green wavelength region, a blue wavelength region, a violet wavelength region, a ultraviolet wavelength region, and the like. In particular, by the light-emitting diode illuminating device, when at least two types of light-emitting diodes emitting visible light having different wavelength regions, such as a red wavelength region, a yellow wavelength region, a green wavelength region, a blue wavelength region, and a violet wavelength region, are combined with each other, and when at least two types of light emitted from the light-emitting diodes are mixed together, natural or white light can be obtained. In addition, when a light-emitting diode emitting light of at least one wavelength region selected from a blue wavelength region, a violet wavelength region, a ultraviolet wavelength region, and the like is used as a light source, and when a phosphor is irradiated with light emitted from the above light-emitting diode for excitation, by mixing at least two types of light obtained thereby, natural or white light can be obtained. In addition, light-emitting diodes emitting visible light of the same wavelength region or different wavelength regions from each other may be assembled to form a cell unit, a quartet unit, or a cluster unit (the number of light-emitting diodes contained in the aforementioned unit is not strictly defined, and when a plurality of equal groups each containing light-emitting diodes having the same wavelength or different wavelengths is formed and is mounted on a wiring board, a wiring package, a wiring housing wall, or the like, the above group is called the unit). That is, in particular, for example, three light-emitting diodes (such as one red light-emitting diode, one green light-emitting diode, and one blue light-emitting diode), four light-emitting diodes (such as one red light-emitting diode, two green light-emitting diodes, and one blue light-emitting diode), or at least five light-emitting diodes may be assembled together to form one unit, and a plurality of the units thus formed may then be mounted on a substrate, a plate, or a housing plate to form a two-dimensional array matrix, one-line pattern, or multiple-line pattern.

In accordance with a fifteenth embodiment of the present invention, there is provided a light-emitting diode comprising; a substrate provided with convex portions on one major surface, the convex portions being composed of a dielectric substance which is different from the substrate and which can change its refractive index by applying a voltage thereto; a fifth nitride-based III-V compound semiconductor layer grown on the substrate without forming a space in a concave portion on the substrate; and a first conductive type third nitride-based III-V compound semiconductor layer, an active layer, and a second conductive type fourth nitride-based III-V compound semiconductor layer, which are provided on the fifth nitride-based III-V compound semiconductor layer; wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

In accordance with a sixteenth embodiment of the present invention, there is provided a light-emitting diode comprising: a fifth nitride-based III-V compound semiconductor layer; and a first conductive type third nitride-based III-V compound semiconductor layer, an active layer, and a second conductive type fourth nitride-based III-V compound semiconductor layer, which are provided on the fifth nitride-based III-V compound semiconductor layer. In the light-emitting diode described above, in one major surface of the fifth nitride-based III-V compound semiconductor layer located at a side opposite to that of the active layer, convex portions composed of a dielectric substance which can change its refractive index by applying a voltage thereto are buried, and in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

In the fifteenth and the sixteenth embodiments of the present invention, as the dielectric substance forming the convex portions and capable of changing its refractive index by voltage application, any material may be basically used, and in particular, for example, there may be used a ferroelectric substance, such as lithium niobate, lithium tantalate, or lanthanum-doped lead zirconate titanate, which preferably does not remarkably absorb light of a light-emitting wavelength. As this ferroelectric substance, besides a material having a stoichiometric composition, a material having a composition slightly deviated therefrom may also be used.

The light-emitting diodes of the fifteenth and the sixteenth embodiment of the present invention may be manufactured by a method similar to that of the first and third embodiments of the present invention. In addition, the fifteenth and the sixteenth embodiments of the present invention may be variously used in a manner similar to that of the second and the fourth embodiment of the present invention.

According to the structures described above of the embodiments of the present invention, when the refractive index of the dielectric substance forming the convex portions is appropriately selected, the far-field pattern of the light-emitting diode can be controlled without using an optical component such as a lens, and when the refractive index is optimized, the light extraction efficiency and the light-scattering property can both be improved. In addition, since the growth of the first nitride-based III-V compound semiconductor layer is started from the bottom surface of the concave portion on the substrate, and the first nitride-based III-V compound semiconductor layer is grown through the state of the triangle cross-sectional shape using the bottom surface of the concave portion as the base, the concave portion can be filled without forming any spaces. Subsequently, from the first nitride-based III-V compound semiconductor layer thus grown, the second nitride-based III-V compound semiconductor layer is grown in the lateral direction. In this step, in the first nitride-based III-V compound semiconductor layer, dislocation is generated from the interface with the bottom surface of the concave portion on the substrate in a direction perpendicular to one major surface of the substrate and then extends to the inclined surface of the first nitride-based III-V compound semiconductor layer or to the vicinity of the inclined surface, and as the second nitride-based III-V compound semiconductor layer is grown, this dislocation is bent in a direction parallel to the major surface of the substrate. When the second nitride-based III-V compound semiconductor layer is grown to have a sufficient thickness, a portion above the dislocation parallel to the major surface of the substrate becomes a region having a significantly low dislocation density. In addition, by the method described above, the first to the fourth nitride-based III-V compound semiconductor layers can be grown by one epitaxial growth. Furthermore, compared to the case in which a concavo-convex structure is directly formed in a substrate by dry etching or the like, the convex portions can be very easily formed on the substrate using a dielectric substance different therefrom, and the process accuracy is also generally high.

According to the embodiments of the present invention, since the refractive index of the dielectric substance forming the convex portions is optimized, and in addition, since spaces between the substrate and the first and/or the second nitride-based III-V compound semiconductor layer are not formed, the light extraction efficiency of the light-emitting diode can be significantly improved. Furthermore, since the crystallinity of the second nitride-based III-V compound semiconductor layer is improved, the crystallinities of the third nitride-based III-V compound semiconductor layer, the active layer, and the fourth nitride-based III-V compound semiconductor layer, which are provided on the second nitride-based III-V compound semiconductor layer, are also significantly improved; hence, the internal quantum efficiency of the light-emitting diode can be improved. Hence, a light-emitting diode having significantly superior luminous efficiency can be obtained. Furthermore, since the light-emitting diode can be manufactured by only one epitaxial growth, the manufacturing cost is low. In addition, the concavo-convex process can be easily performed on the substrate, and the process accuracy is also high. Accordingly, by using the light-emitting diodes having a high luminous efficiency, for example, light source cell units, light-emitting diode backlights, light-emitting diode illuminating devices, light-emitting diode displays, light-emitting diode optical communication devices, optical space transmission devices, and various electronic apparatuses, each having high performance, can be realized.

### BRIEF DESCRIPTION OF THE DRAWINGS

FIG. 1 is a cross-sectional view of a light-emitting diode illustrating the present invention;

FIG. 2 is a cross-sectional view of a light-emitting diode illustrating the present invention;

FIG. 3 is a graph showing radiation distributions from an upper surface and a side surface of the light-emitting diode shown in FIG. 2;

FIG. 4A is a cross-sectional view showing an example of convex portions formed on a substrate of the light-emitting diode shown in FIG. 1;

FIG. 4B is a plan view showing an example of the convex portions formed on the substrate of the light-emitting diode shown in FIG. 1;

FIG. 5 is a graph showing the change in light extraction magnification and the change in side-surface luminous ratio by an interference phenomenon in the light-emitting diode shown in FIG. 2;

FIG. 6 is a graph showing the change in shape of a far-field pattern with the change in side-surface luminous ratio of the light-emitting diode sown in FIGS. 1, 4A, and 4B;

FIGS. 7A and 7B are graphs each showing the change in light extraction magnification and the change in side-surface luminous ratio with the change in refractive index of the convex portion of the light-emitting diode shown in FIGS. 1, 4A, and 4B;

FIG. 8 is a cross-sectional view of a light-emitting diode after a substrate is removed;

FIG. 9 is a graph showing the change in light extraction magnification and the change in side-surface luminous ratio with the change in refractive index of a convex portion of the light-emitting diode shown in FIG. 8;

FIGS. 10A to 10C are each a cross-sectional view illustrating a method for manufacturing a light-emitting diode according to a first embodiment of the present invention;

FIGS. 11A to 11C are each a cross-sectional view illustrating the method for manufacturing a light-emitting diode according to the first embodiment of the present invention;

FIG. 12 is a cross-sectional view illustrating the method for manufacturing a light-emitting diode according to the first embodiment of the present invention;

FIG. 13 is a plan view showing an example of convex portions formed on a substrate by the method for manufacturing a light-emitting diode according to the first embodiment of the present invention;

FIG. 14 is a plan view showing an example of the convex portions formed on the substrate by the method for manufacturing a light-emitting diode according to the first embodiment of the present invention;

FIG. 15 is a plan view of a light-emitting diode manufactured by the method for manufacturing a light-emitting diode according to the first embodiment of the present invention;

FIG. 16 is a schematic cross-sectional view of a nitride-based III-V compound semiconductor layer and convex portions used in the method for manufacturing a light-emitting diode according to the first embodiment of the present invention;

FIG. 17 is a schematic view illustrating the growth of the nitride-based III-V compound semiconductor layer on a substrate by the method for manufacturing a light-emitting diode according to the first embodiment of the present invention;

FIG. 18 is a schematic view illustrating the behavior of dislocation obtained by TEM observation of the nitride-based III-V compound semiconductor layer grown on a substrate by the method for manufacturing a light-emitting diode according to the first embodiment of the present invention;

FIG. 19 is a schematic view showing an example of the distribution of threading dislocations in the nitride-based III-V compound semiconductor layer grown on the substrate by the method for manufacturing a light-emitting diode according to the first embodiment of the present invention;

FIG. 20 is a schematic view showing an example of the distribution of threading dislocations in the nitride-based III-V compound semiconductor layer grown on the substrate by the method for manufacturing a light-emitting diode according to the first embodiment of the present invention;

FIGS. 21A to 21F are each a schematic view showing the growth of the nitride-based III-V compound semiconductor layer on the substrate by the method for manufacturing a light-emitting diode according to the first embodiment of the present invention;

FIGS. 22A and 22B are each a schematic view illustrating the behavior of dislocation of the nitride-based III-V compound semiconductor layer grown on the substrate by the method for manufacturing a light-emitting diode according to the first embodiment of the present invention;

FIGS. 23A to 23C are each a photograph showing the state at the early growth stage of the nitride-based III-V compound semiconductor layer grown on the substrate by the method for manufacturing a light-emitting diode according to the first embodiment of the present invention;

FIGS. 24A to 24C are each a schematic view showing the case of the method for manufacturing a light-emitting diode according to the first embodiment of the present invention in which a nitride-based III-V compound semiconductor layer grown on a substrate without generating minute nuclei at the early growth stage;

FIGS. 25A and 25B are each a schematic view showing the case of the method for manufacturing a light-emitting diode according to the first embodiment of the present invention in which a nitride-based III-V compound semiconductor layer grown on a substrate without generating minute nuclei at the early growth stage;

FIGS. 26A and 26B are each a cross-sectional view illustrating a method for manufacturing a light-emitting diode according to a second embodiment of the present invention;

FIG. 27 is a cross-sectional view illustrating a method for manufacturing a light-emitting diode according to a third embodiment of the present invention;

FIG. 28 is a cross-sectional view illustrating the method for manufacturing a light-emitting diode according to the third embodiment of the present invention;

FIGS. 29A to 29C are each a cross-sectional view illustrating a method for manufacturing a light-emitting diode according to a fourth embodiment of the present invention;

FIG. 30 is a cross-sectional view illustrating the method for manufacturing a light-emitting diode according to the fourth embodiment of the present invention;

FIG. 31 is a schematic view illustrating the behavior of dislocation obtained by TEM observation of a nitride-based III-V compound semiconductor layer grown on a substrate by the method for manufacturing a light-emitting diode according to the fourth embodiment of the present invention;

FIG. 32 is a graph showing the measurement results of a far-field pattern of an example of the light-emitting diode manufactured in the fourth embodiment of the present invention;

FIG. 33 is a cross-sectional view illustrating a method for manufacturing a light-emitting diode according to a fifth embodiment of the present invention;

FIGS. 34A and 34B are each a cross-sectional view illustrating a method for manufacturing a light-emitting diode according to a sixth embodiment of the present invention;

FIGS. 35A and 35B are each a cross-sectional view illustrating the method for manufacturing a light-emitting diode according to the sixth embodiment of the present invention;

FIG. 36 is a plan view showing an example of a planar shape of a convex portion formed on a substrate by the method for manufacturing a light-emitting diode according to the sixth embodiment of the present invention;

FIGS. 37A to 37J are each a cross-sectional view illustrating a method for manufacturing a light-emitting diode according to a seventh embodiment of the present invention;

FIGS. 38A to 38C are each a cross-sectional view illustrating a method for manufacturing a light-emitting diode backlight according to an eighth embodiment of the present invention;

FIG. 39 is a perspective view illustrating the method for manufacturing a light-emitting diode backlight according to the eighth embodiment of the present invention;

FIG. 40 is a perspective view illustrating the method for manufacturing a light-emitting diode backlight according to the eighth embodiment of the present invention;

FIG. 41 is a perspective view illustrating a method for manufacturing a light-emitting diode backlight according to a ninth embodiment of the present invention;

FIG. 42A is a plan view showing a light source cell unit according to a tenth embodiment of the present invention;

FIG. 42B is an enlarged view showing the light source cell unit according to the tenth embodiment of the present invention;

FIG. 43 is a plan view showing one concrete example of the light source cell unit according to the tenth embodiment of the present invention;

FIG. 44 is a plan view showing another concrete example of the light source cell unit according to the tenth embodiment of the present invention;

FIG. 45 is a plan view showing another structural example of the light source cell unit according to the tenth embodiment of the present invention;

FIGS. 46A to 46C are each a cross-sectional view illustrating a related method for growing a GaN-based semiconductor layer on a concavo-convex substrate;

FIG. 47 is a cross-sectional view illustrating a problem of the related method for growing a GaN-based semiconductor layer shown in FIGS. 46A to 46C;

FIGS. 48A to 46D are each a cross-sectional view illustrating a related method for growing a GaN-based semiconductor layer on a concavo-convex substrate; and

FIGS. 49A to 49F are each a cross-sectional view illustrating another related method for growing a GaN-based semiconductor layer on a concavo-convex substrate.

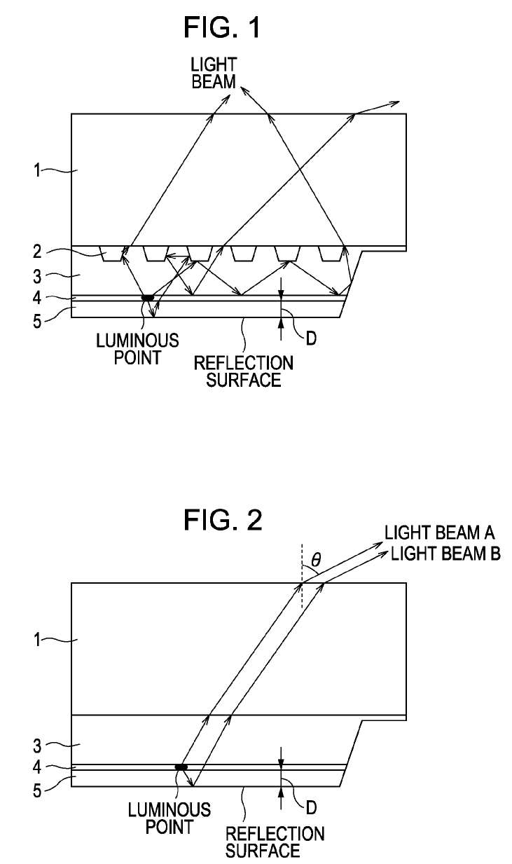

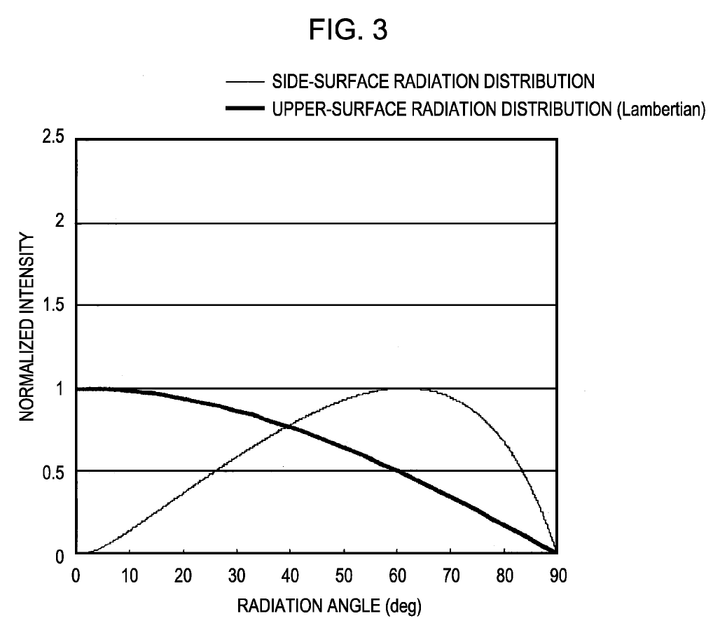

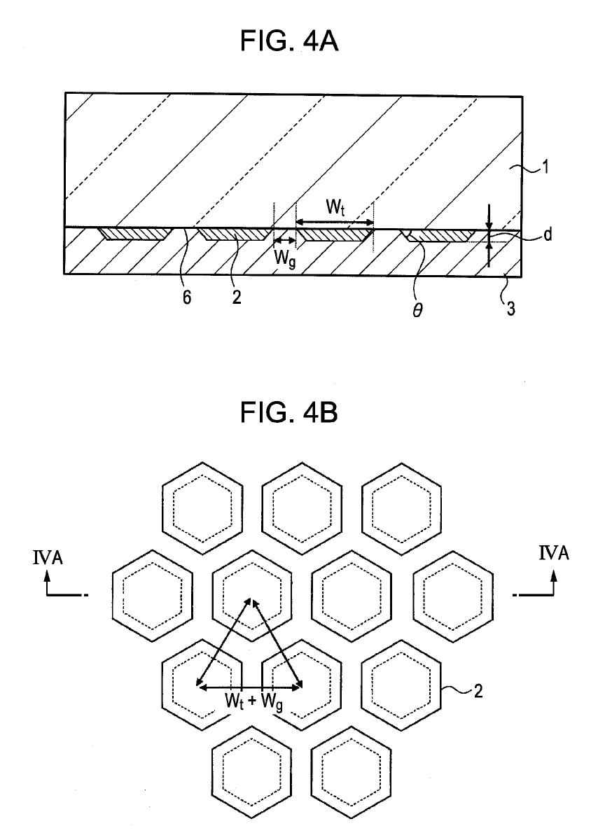

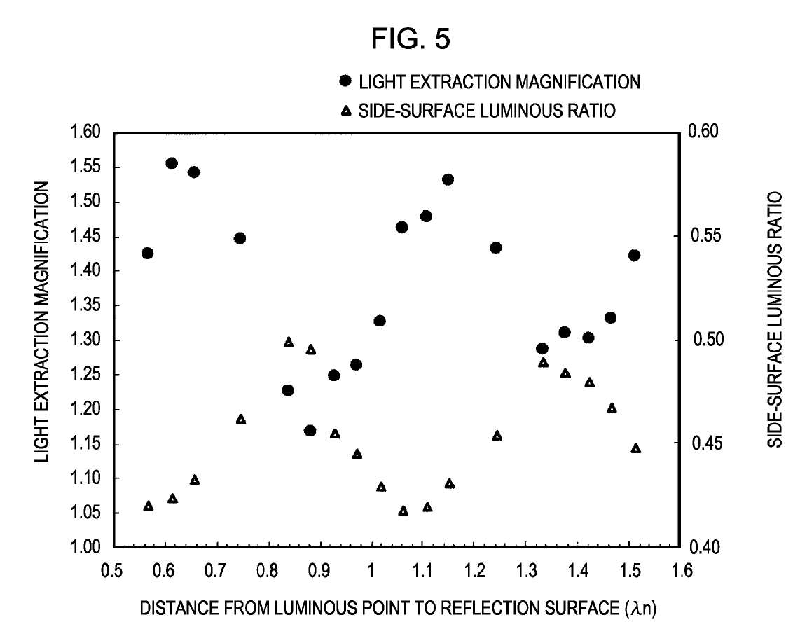

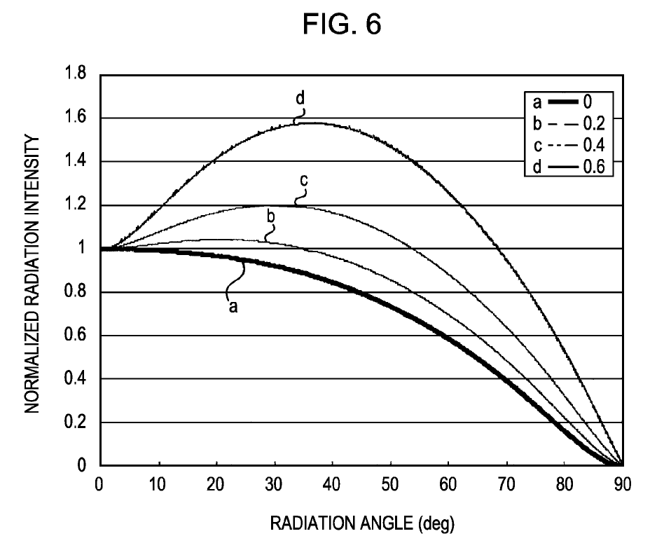

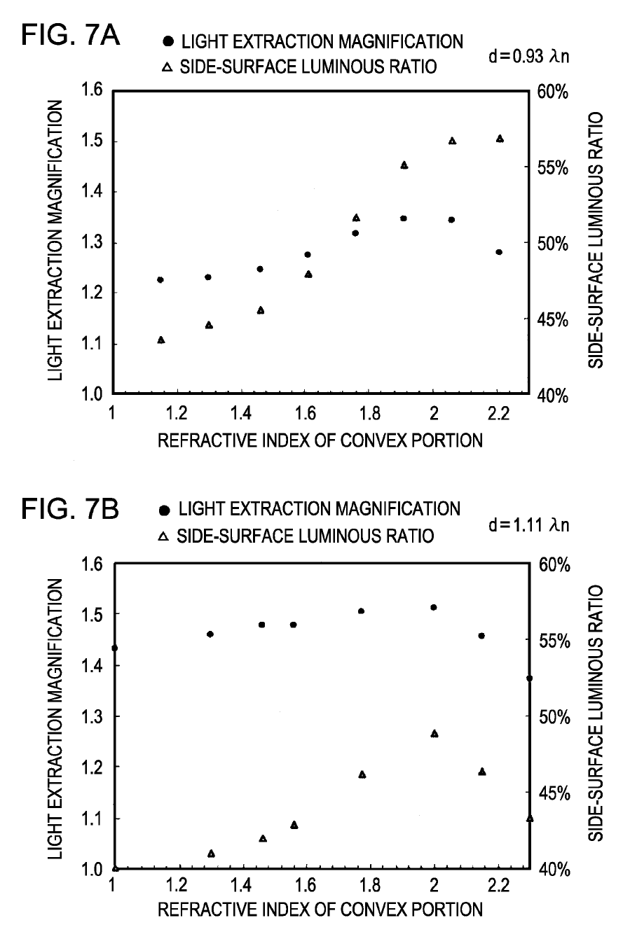

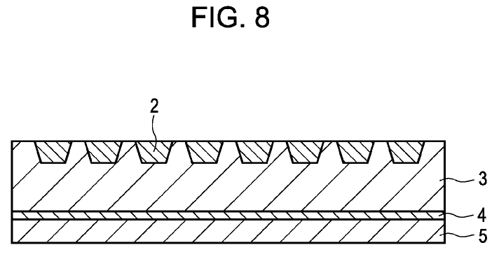

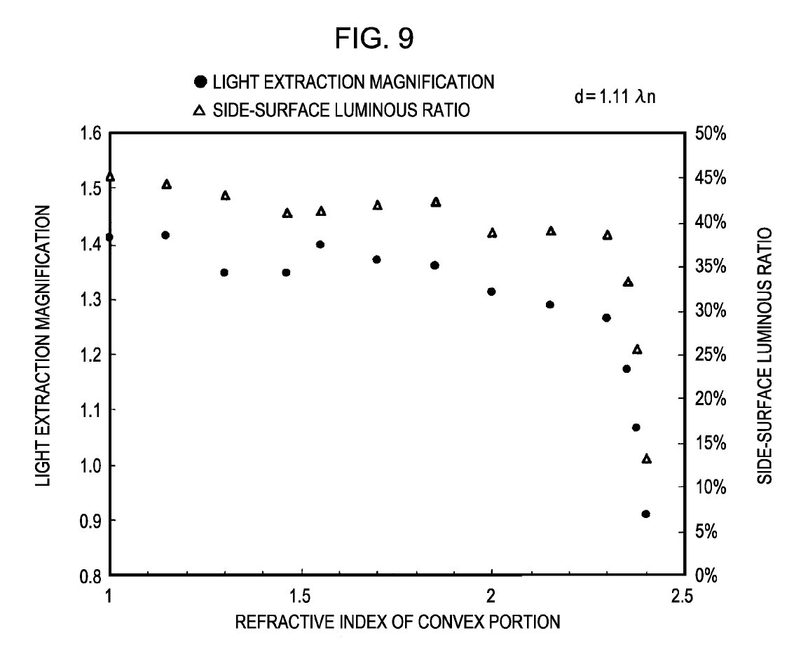

### DESCRIPTION OF THE PREFERRED EMBODIMENTS

Hereinafter, the embodiments of the present invention will be described with reference to the accompanying drawings. In all the drawings of the embodiments, the same reference numerals designate the same or corresponding parts.

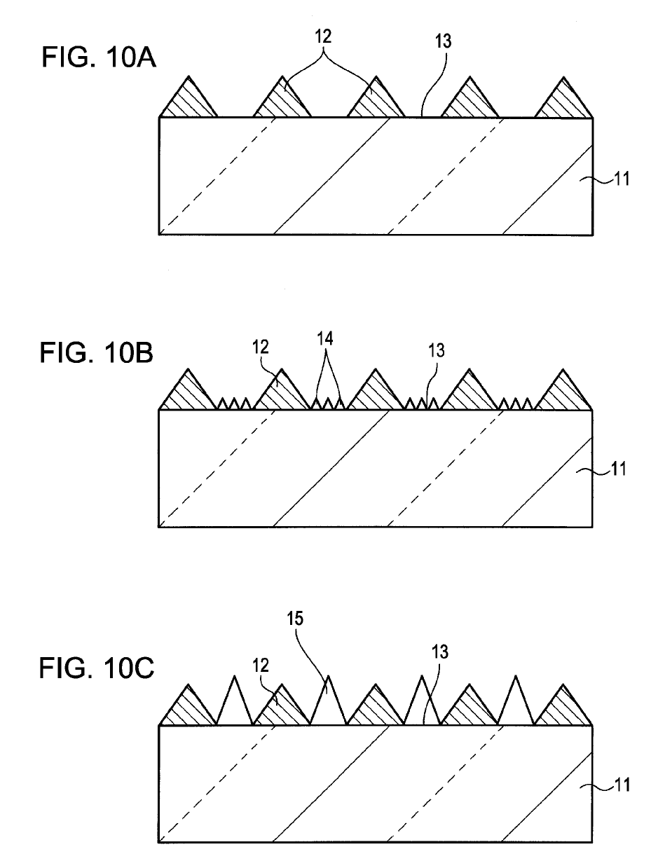

FIGS. 10A to 12 show a manufacturing method of a light-emitting diode according to an embodiment of the present invention in the order of manufacturing steps. This light-emitting diode uses a nitride-based III-V compound semiconductor such as GaN and is a flip chip type (FC type) light-emitting diode in which a substrate transparent to light having a light-emitting wavelength is used and in which light emission is performed from the entire rear surface of this transparent substrate.

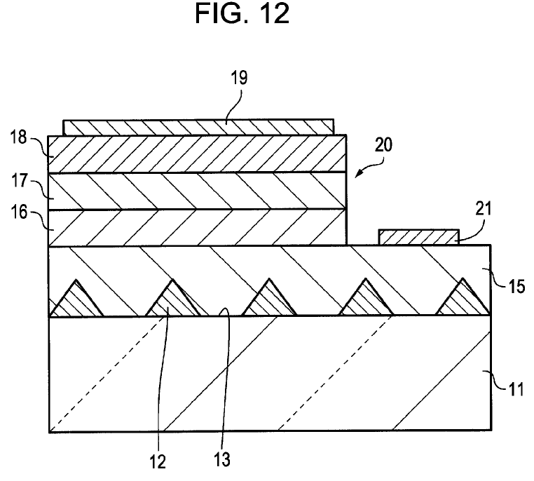

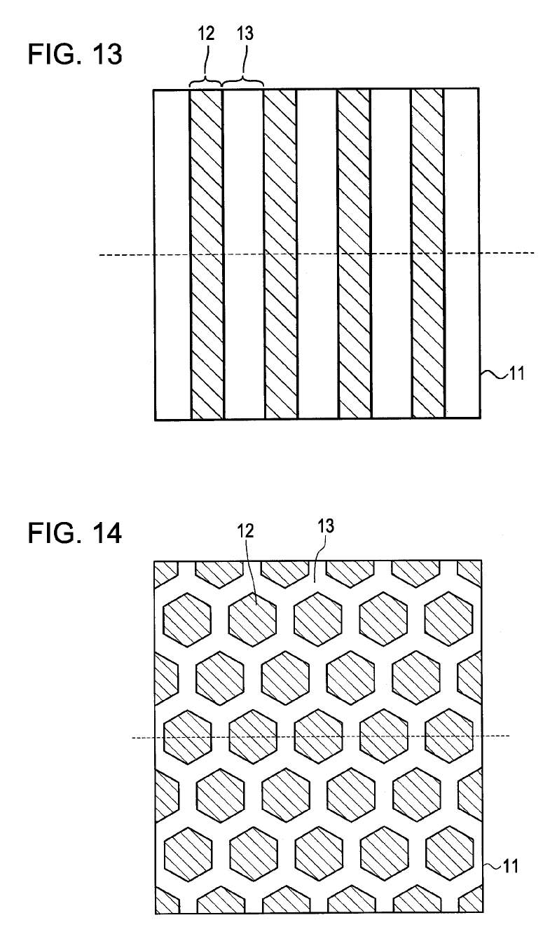

In this first embodiment, as shown in FIG. 10A, a substrate 11 having one flat major surface and formed of a material different from a nitride-based III-V compound semiconductor is prepared, and convex portions 12 each having a predetermined planar shape and an isosceles triangle cross-sectional shape are formed periodically on this substrate 11. Concave portions 13 each having an inverted trapezoid cross-sectional shape are formed between the convex portions 12. As this substrate 11, for example, the materials described above may be used; however, in particular, for example, a sapphire substrate is used, and the major surface thereof is, for example, the c-plane. The convex portion 12 and the concave portion 13 may have various planar shapes as described above, and for example, as shown in FIG. 13, the convex portions 12 and the concave portions 13 each may have a stripe pattern extending in one direction, or as shown in FIG. 14, the convex portions 12 each may have a hexagonal planar shape and may be two-dimensionally arranged to form a honeycomb pattern. Typically, the direction (direction orthogonal to the stripe pattern) of a dotted line in FIG. 13 is set parallel to the a axis of a nitride-based III-V compound semiconductor layer 15 which will be described later, and the direction (direction between closest adjacent convex portions 12) of a dotted line in FIG. 14 is set parallel to the m axis of the nitride-based III-V compound semiconductor layer 15. For example, when the substrate 11 is a sapphire substrate, the extending directions of the convex portions 12 and the concave portions 13 in the stripe pattern shown in FIG. 13 is the <1-100> direction of the sapphire substrate, and the extending direction of the concave portions 13 shown in FIG. 14 is also the <1-100> direction of the sapphire substrate. These extending directions may be the <11-20> direction of the sapphire substrate. As the material for the convex portions 12, a dielectric substance having a refractive index of 1.7 to 2.2, such as CeO₂, HfO₂, Ta₂O₅, Y₂O₃, ZnO, ZrO₂, rhombic sulfur, LiTaO₃, LiNbO₃, AlON, SiO, Si₃N₄, Al₂O₃, BeO, or MgO, may be used and may be, for example, appropriately selected therefrom.

In order to form the convex portions 12 each having an isosceles triangle on the substrate 11, a related known technique may be used. For example, by a CVD method, a vacuum deposition method, or a sputtering method, a dielectric film used as a material for the convex portions 12 is formed over the entire surface of the substrate 11. Next, a resist pattern having a predetermined shape is formed on this dielectric film by lithography. Subsequently, by a reactive ion etching (RIE) method or the like, under the conditions in which a taper etching can be performed, this dielectric film is etched using this resist pattern as a mask, so that the convex portions 12 each having an isosceles triangle cross-sectional shape can be formed.

Next, after surfaces of this substrate 11 and the convex portions 12 are cleaned by thermal cleaning or the like, a GaN buffer layer, an AlN buffer layer, a CrN buffer layer, a Cr-doped GaN buffer layer, or a Cr-doped AlN buffer layer (not shown) is formed on this substrate 11 by a related known method at a growth temperature of approximately 550° C. or the like. Subsequently, epitaxial growth of a nitride-based III-V compound semiconductor is performed, for example, by an MOCVD method. This nitride-based III-V compound semiconductor is, for example, GaN. In this case, as shown in FIG. 10B, the growth is first started from the bottom surface of the concave portion 13, and minute nuclei 14 composed of the nitride-based III-V compound semiconductor are formed. Subsequently, as shown in FIG. 10C, through the process including the growth and coalescence of the minute nuclei 14, the nitride-based III-V compound semiconductor layer 15 is grown to form an isosceles triangle cross-sectional shape having facets inclined with respect to the major surface of the substrate 11 as inclined surfaces, this triangle using the bottom surface of the concave portion 13 as the base. In this example, the height of the nitride-based III-V compound semiconductor layer 15 having an isosceles triangle cross-sectional shape is larger than the height of the convex portion 12. For example, the extending direction of the nitride-based III-V compound semiconductor layer 15 is its <1-100> direction, and its inclined facet is the (1-101) plane. This nitride-based III-V compound semiconductor layer 15 may be un-doped or may be doped with an n-type or a p-type impurity. The growth conditions of this nitride-based III-V compound semiconductor layer 15 will be described later. The extending direction of the nitride-based III-V compound semiconductor layer 15 may also be its <11-20> direction.

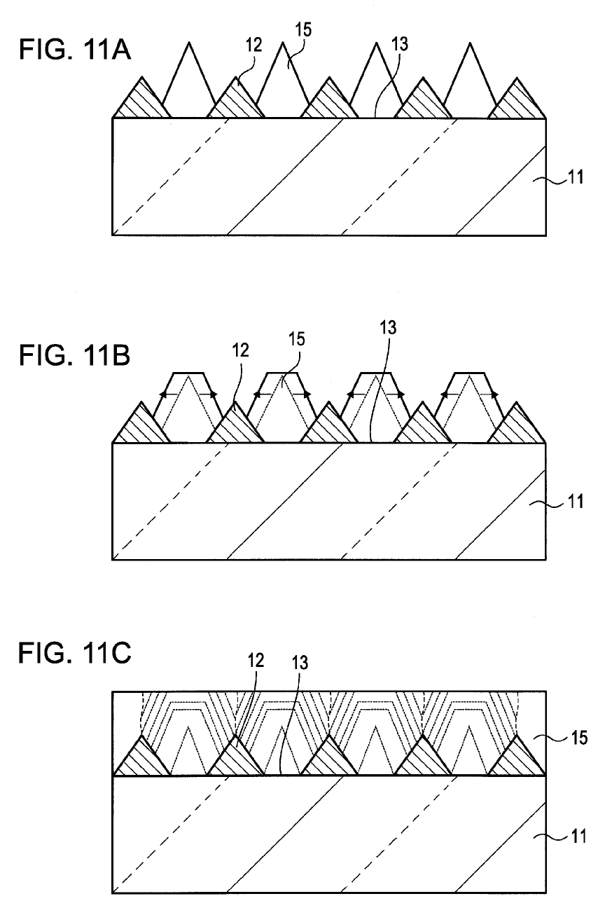

Subsequently, when the nitride-based III-V compound semiconductor is grown while the facet plane orientation of the inclined surface is maintained, as shown in FIG. 11A, the two ends of the nitride-based III-V compound semiconductor 15 are grown to the lower portions of the side surfaces of the convex portions 12, so that a pentagonal cross-sectional shape is formed.

Next, when the growth conditions are set so that lateral direction growth preferentially occurs, and the growth is further advanced, as shown in FIG. 11B, the nitride-based III-V compound semiconductor layer 15 is grown in the lateral directions as shown by arrows and is expanded on the convex portions 12 so as to have a hexagonal cross-sectional shape. In FIG. 11B, dotted lines indicate growth interfaces formed during the growth (hereinafter, the dotted line indicates the same as described above).

When the lateral direction growth is further continued, as shown in FIG. 11C, the nitride-based III-V compound semiconductor layer 15 is grown while increasing it thickness, and finally, the nitride-based III-V compound semiconductor layers 15 grown from adjacent concave portions 13 are brought into contact with each other above the convex portion 12, so that the coalescence occurs (hereinafter, the coalescent nitride-based III-V compound semiconductor layers 15 as described above may be collectively called the nitride-based III-V compound semiconductor layer 15 in some cases).

Subsequently, as shown in FIG. 11C, the nitride-based III-V compound semiconductor layers 15 are further grown in the lateral direction until the surfaces thereof form one flat surface parallel to the major surface of the substrate 11. The nitride-based III-V compound semiconductor layers 15 thus grown have a significantly low dislocation density in a region above the concave portion 13.

In addition, depending on the case, from the state shown in FIG. 10C, the state shown in FIG. 11B can be directly obtained without passing through the state shown in FIG. 11A.

Next, as shown in FIG. 12, on the nitride-based III-V compound semiconductor layer 15, for example, by an MOCVD method, an n-type nitride-based III-V compound semiconductor layer 16, an active layer 17 using a nitride-based III-V compound semiconductor, and a p-type nitride-based III-V compound semiconductor layer 18 are sequentially epitaxially grown. In this case, the nitride-based III-V compound semiconductor layer 15 is an n-type.

Subsequently, the substrate 11 on which the nitride-based III-V compound semiconductor layers are formed as described above is recovered from an MOCVD apparatus.

Next, a p-side electrode 19 is formed on the p-type nitride-based III-V compound semiconductor layer 18. As a material for the p-side electrode 19, an ohmic metal having a high reflectance to light having a light-emitting wavelength is preferably used.

Subsequently, in order to activate a p-type impurity of the p-type nitride-based III-V compound semiconductor layer 18, for example, in a mixed gas atmosphere containing N₂ and O₂ (containing, for example, 99% of N₂ and 1% of O₂), heat treatment is performed at 550 to 750° C. (such as 650° C.) or 580 to 620° C. (such as 600° C.). In this step, for example, by mixing N₂ and O₂, activation can be easily obtained. In addition, for example, as a raw material for F, Cl, or the like, which has a high electronegativity similar to that of O and N, a halogenated nitride (NF₃, NCl₃, or the like) may be mixed in an N₂ atmosphere or a mixed gas atmosphere of N₂ and O₂. The time for this heat treatment is, for example, 5 minutes to 2 hours or 40 minutes to 2 hours, or is generally approximately 10 to 60 minutes. The reason the heat treatment is performed at a relatively low temperature is to prevent the degradation of the active layer 17 during the heat treatment. In addition, this heat treatment may be performed after the p-type nitride-based III-V compound semiconductor layer 18 is epitaxially grown and before the p-side electrode 19 is formed.

Subsequently, the n-type nitride-based III-V compound semiconductor layer 16, the active layer 17, and the p-type nitride-based III-V compound semiconductor layer 18 are patterned into a predetermined shape by an RIE method, a powder blast method, a sandblast method, or the like, so that a mesa portion 20 is formed.

Next, on part of the n-type nitride-based III-V compound semiconductor layer 15 adjacent to this mesa portion 20, an n-side electrode 21 is formed.

Subsequently, whenever necessary, after the substrate 11 on which the light-emitting diode structure is formed as described above is polished or lapped from the rear surface side to decrease the thickness, scribing of this substrate 11 is performed, so that bars are formed. Next, the bars are scribed, so that chips are formed.

By the steps as described above, an intended light-emitting diode can be manufactured.

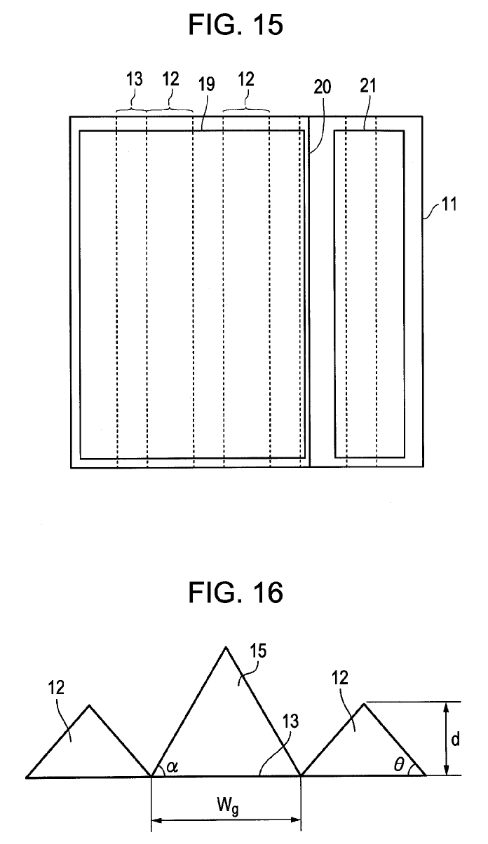

The planar shapes of the p-side electrode 19 and the n-side electrode 21 are shown by way of example in FIG. 15 in the case in which the convex portions 12 extend in one direction to have a stripe pattern.

As raw materials of the above nitride-based III-V compound semiconductor layers, for example, triethylgallium ((C₂H₅)₃Ga, TEG) or trimethylgallium ((CH₃)₃Ga, TMG) is used as a raw material for Ga; trimethylaluminum ((CH₃)₃Al, TMA) is used as a raw material for Al; triethylindium ((C₂H₅)₃In, TEI) or trimethylindium ((CH₃)₃In, TMI) is used as a raw material for In; and ammonia (NH₃) is used as a raw material for N. As for a dopant, for example, silane (SiH₄) or disilane (Si₂H₆) is used as an n-type dopant; bis(methylcyclopentadienyl)magnesium ((CH₃C₅H₄)₂Mg), bis(ethylcyclopentadienyl)magnesium ((C₂H₅C₅H₄)₂Mg), or bis(cyclopentadienyl)magnesium ((C₅H₅)₂Mg) is used as a p-type dopant. In addition, as a carrier gas atmosphere during the growth of the nitride-based III-V compound semiconductor layers, for example, a H₂ gas is used.

A particular structural example of this light-emitting diode will be described. That is, for example, the nitride-based III-V compound semiconductor layer 15 is an n-type Gan layer, the n-type nitride-based III-V compound semiconductor layer 16 is formed of an n-type GaN layer and an n-type GaInN layer in that order from the bottom, and the p-type nitride-based III-V compound semiconductor layer 18 is formed of a p-type AlInN layer, a p-type GaN layer, and a p-type GaInN layer in that order from the bottom. The active layer 17 has, for example, a GaInN-based multiquantum well (MQW) structure (for example, a GaInN quantum well layer and a GaN barrier layer are alternately laminated to each other), and the In composition of this active layer 17 is selected in accordance with a light-emitting wavelength of the light-emitting diode and is, for example, 11% or less at a light-emitting wavelength of 405 nm, 18% or less at a wavelength of 450 nm, and 24% or less at a wavelength of 520 nm. As a material for the p-side electrode 19, for example, Ag or Pd/Ag is used, or whenever necessary, besides the above metal, a barrier metal containing Ti, W, Cr, WN, CrN, or the like is used. As the n-side electrode 21, for example, a Ti/Pt/Au structure may be used.

In the light-emitting diode shown in FIG. 12 thus obtained, current is allowed to pass by applying a forward voltage between the p-side electrode 19 and the n-side electrode 21 for light emission, so that light is extracted outside through the substrate 11. By the selection of the In composition of the active layer 17, light emission from red to violet color, and in particular, blue, green, and red light emission can be obtained. In this case, by the concavo-convex structure of the concave portions 13 and the convex portions 12 formed from a dielectric substance having a refractive index of 1.7 to 2.2, the reflection angle of light emitted from the active layer 17 can be changed, and hence the number of light beams entering the escape cone is increased, so that the light extraction efficiency can be improved.

In this first embodiment, in order to minimize the threading dislocation density of the nitride-based III-V compound semiconductor layer 15, the width Wg of the bottom of the concave portion 13, the depth thereof, that is, the height d of the convex portion 12, and the angle α formed between the major surface of the substrate 11 and the inclined surface of the nitride-based III-V compound semiconductor layer 15 in the state shown in FIG. 10C are determined so as to satisfy the following equation (see FIG. 16).

2 d>Wg·tan α

For example, when Wg is 2.1 μm and α is 59°, d is 1.75 μm or more; when Wg is 2 μm and α is 59°, d is 1.66 μm or more; when Wg is 1.5 μm and α is 59°, d is 1.245 μm or more; and when Wg is 1.2 μm and α is 59°, d is 0.966 μm or more. However, in all the cases, d is preferably set to less than 5 μm.

When the nitride-based III-V compound semiconductor layer 15 is grown in the steps shown in FIGS. 10B, 10C, and 11A, it is preferable that the V/III raw material ratio be set high and the growth temperature be set low. In particular, when the nitride-based III-V compound semiconductor layer 15 is grown under a pressure condition of 1 atmosphere, the V/III raw material ratio and the growth temperature are preferably set, for example, in the range of 13,000±2,000 and 1,100±50° C., respectively. When the nitride-based III-V compound semiconductor layer 15 is grown under a pressure condition of x atmospheres, from Bernoulli's principle that defines the relationship between the flow velocity and the pressure, the V/III raw material ratio is preferably determined by multiplying the V/III ratio at 1 atmosphere by the square of the pressure x, that is, is preferably set to approximately (13,000±2,000)×x². For example, when the growth is performed at a pressure of 0.92 atmospheres (700 Torr), the V/III raw material ratio is preferably set in the range of 11,000±1,700 (such as 10,530). In addition, x is generally 0.01 to 2 atmospheres. As for the growth temperature, when the growth is performed at a pressure of 1 atmosphere or less, in order to suppress the lateral direction growth of the nitride-based III-V compound semiconductor layer 15 and to facilitate selective growth thereof from the concave portion 13, a lower growth temperature is preferably set. For example, when the growth is performed at a pressure of 0.92 atmospheres (700 Torr), the growth temperature is preferably set in the range of 1,050±50° C. (such as 1,050° C.). Accordingly, the nitride-based III-V compound semiconductor layer 15 is grown as shown in FIGS. 10B, 10C, and 11A. In this case, the growth of the nitride-based III-V compound semiconductor layer 15 is not started from the convex portion 12. The growth rate is generally 0.5 to 5.0 μm/h and is preferably set to approximately 3.0 μm/h. When the nitride-based III-V compound semiconductor layer 15 is a GaN layer, as for the flow rate of the raw material gas, for example, TMG is 20 sccm, and NH₃ is 20 slm. On the other hand, for the growth (lateral direction growth) of the nitride-based III-V compound semiconductor layer 15 in the steps shown in FIGS. 11B and 11C, the V/III raw material ratio and the growth temperature are set to low and high, respectively. In particular, when the nitride-based III-V compound semiconductor layer 15 is grown under a pressure condition of 1 atmosphere, the V/III raw material ratio and the growth temperature are set, for example, in the range of 5,000±2,000 and 1,200±50° C., respectively. When the nitride-based III-V compound semiconductor layer 15 is grown under a pressure condition of x atmospheres, from Bernoulli's principle that defines the relationship between the flow velocity and the pressure, the V/III raw material ratio is preferably determined by multiplying the V/III ratio at 1 atmosphere by the square of the pressure x, that is, is preferably set to approximately (5,000±2,000)×x². For example, when the growth is performed at a pressure of 0.92 atmospheres (700 Torr), the V/III raw material ratio is preferably set in the range of 4,200±1,700 (such as 4,232). As for the growth temperature, when the growth is performed at a pressure of 1 atmosphere or less, in order to prevent coarsening of the surface of the nitride-based III-V compound semiconductor layer 15 and to preferably perform the lateral direction growth, a lower growth temperature is preferably set. For example, when the growth is performed at a pressure of 0.92 atmospheres (700 Torr), the growth temperature is preferably set in the range of 1,150±50° C. (such as 1,110° C.). When the nitride-based III-V compound semiconductor layer 15 is a GaN layer, as for the flow rate of the raw material gas, for example, TMG is 40 sccm, and NH₃ is 20 slm. Accordingly, the nitride-based III-V compound semiconductor layer 15 is grown in the lateral direction as shown in FIGS. 11B and 11C.

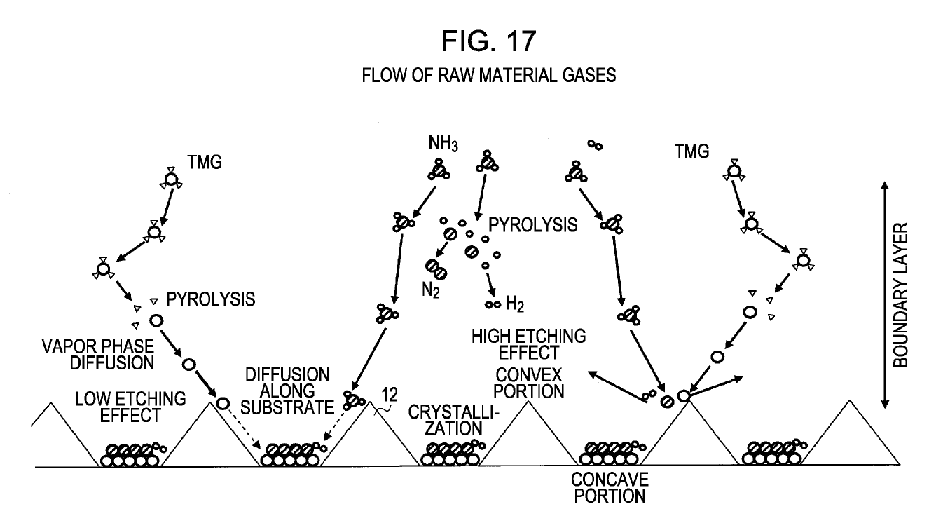

In FIG. 17, the flow of raw material gases and the diffusion thereof along the substrate 11 during the growth of a GaN layer, which is one example of the nitride-based III-V compound semiconductor layer 15, are shown. The most important point during this growth is that at the early growth stage, GaN is not grown on the convex portions 12 and is grown only on the concave portions 13. In FIG. 17, although the cross-sectional shape of the convex portion 12 is a triangle, even when the cross-sectional shape thereof is a trapezoid, as is the case described above, GaN is not grown on the convex portions 12. In the case in which GaN is grown using TMG as a raw material for Ga and NH₃ as a raw material for N, the reactions are represented as follows, and GaN is obtained by direct reaction between NH₃ and Ga.

Ga(CH₃)₃ (g)+3/2 H₂ (g)→Ga (g)+3CH₄ (g) NH₃ (g)→(1−α)NH₃ (g)+α/2 N₂ (g)+3α/2 H₂ (g) Ga (g)+NH₃ (g)=GaN (s)+3/2 H₂ (g)

According to this reaction, H₂ gas is generated, and this H₂ gas has as an opposite function, that is, has an etching function. In the steps shown in FIGS. 10B, 10C and 11A, under conditions different from those performed in the past in which GaN is grown on a flat substrate, that is, under conditions in which the etching function is enhanced so that the growth is not easily performed (the V/III ratio is increased), the growth on the convex portions 12 is suppressed. On the other hand, in the concave portions 13, since the etching function is decreased, the crystal growth occurs. Furthermore, in order to improve the flatness of the grown crystal surface, growth is performed in the past so that the degree of the lateral direction growth is enhanced (at a higher temperature); however, in this first embodiment, in order to suppress the threading dislocation by bending it in a direction parallel to the major surface of the substrate 11 and/or to fill the concave portions 13 with the nitride-based III-V compound semiconductor layer 15 at an earlier stage, the growth is carried out at a lower temperature (such as 1,050±50° C.) than that in the past as described above.

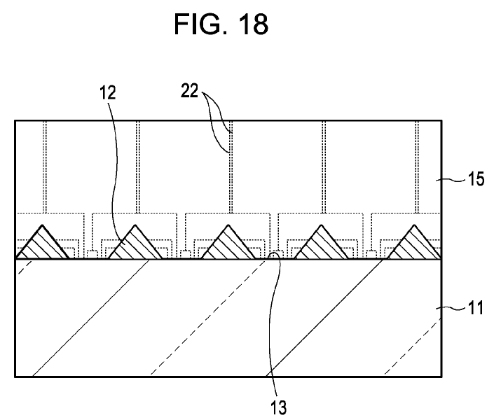

In FIG. 18, the crystalline defect distribution in the nitride-based III-V compound semiconductor layer 15 measured by a transmission electron microscope (TEM) is schematically shown. In FIG. 18, reference numeral 22 indicates a threading dislocation. As can be seen from FIG. 18, in the vicinity of the central portion of the convex portion 12, that is, at the coalescent portion at which the nitride-based III-V compound semiconductor layers 15 grown from adjacent concave portions 13 come into contact with each other, the dislocation density is increased; however, at the other portions including the portion above the concave portion 13, the dislocation density is low. For example, when the depth d of the concave portion 13 is 1 μm and the width Wg of the bottom surface is 2 μm, the dislocation density at this low-dislocation density portion is 6×10⁷/cm², and compared to the case using the substrate 11 which is not processed by irregularity-forming process, the dislocation density is decreased by one to two orders of magnitude. It is also found that dislocation in a direction perpendicular to the side walls of the concave portion 13 does not occur at all.

In addition, in FIG. 18, the average thickness of a part of the nitride-based III-V compound semiconductor layer 15, which is in contact with the substrate 11 at the concave portion 13 and which is in the region having a high dislocation density and inferior crystallinity, is approximately 1.5 times the thickness of a part of the nitride-based III-V compound semiconductor layer 15, which is on the convex portion 12 and which is in the region having a high dislocation density and inferior crystallinity. The reason for this is that the nitride-based III-V compound semiconductor layer 15 is grown in the lateral direction on the convex portions 12.

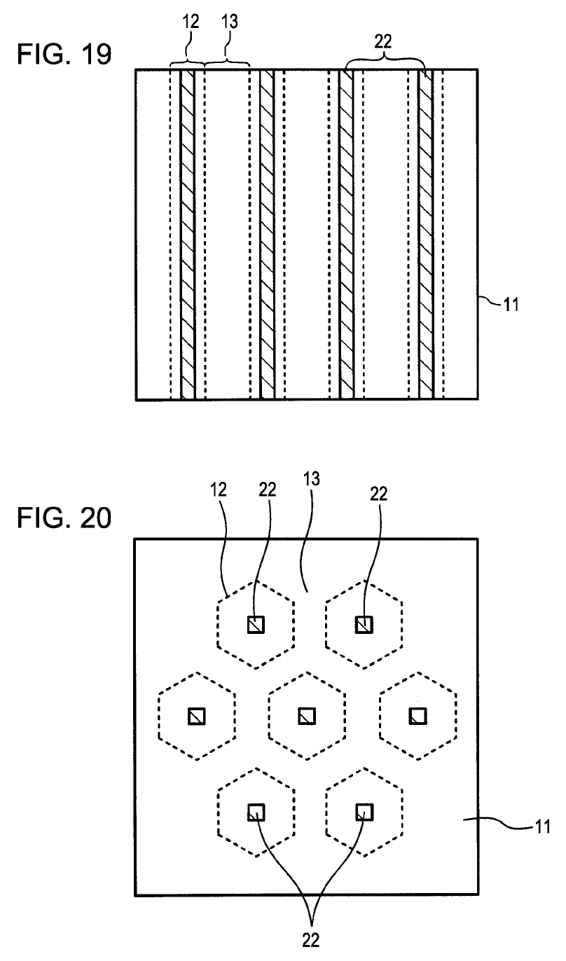

In FIG. 19, the distribution of threading dislocations 22 is shown which is obtained when the convex portion 12 has a planar shape shown in FIG. 13. In addition, in FIG. 20, the distribution of the threading dislocations 22 is shown which is obtained when the convex portion 12 has a planar shape shown in FIG. 14.

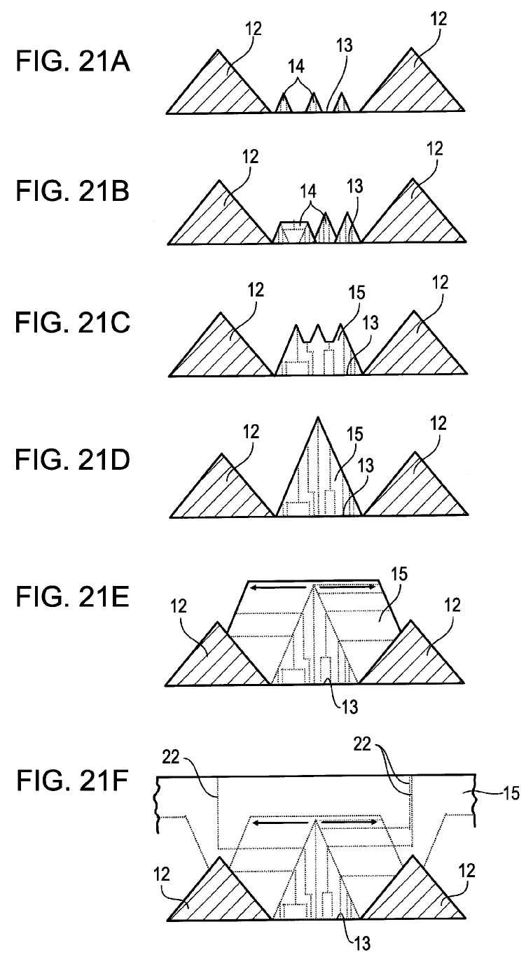

Next, the growth behavior of the nitride-based III-V compound semiconductor layer 15 from the early growth stage and the propagation behavior of dislocations will be described with reference to FIG. 21.

When the growth starts, as shown in FIG. 21A, the minute nuclei 14 formed of a nitride-based III-V compound semiconductor are first generated on the bottom surface of the concave portion 13. In these minute nuclei 14, dislocations (shown by dotted lines) are generated from the interface with the substrate 11 in a direction perpendicular thereto and are propagated to the side surfaces of the minute nuclei 14. When the growth is continued, as shown in FIGS. 21B and 21C, through the process including the growth and coalescence of the minute nuclei 14, the nitride-based III-V compound semiconductor layer 15 is grown. During the process including the growth and coalescence of the minute nuclei 14, the dislocations are bent in a direction parallel to the major surface of the substrate 11, and as a result, the number of dislocations propagated to the upper side is decreased. When the growth is further continued, as shown in FIG. 21D, the nitride-based III-V compound semiconductor layer 15 is grown to have an isosceles triangle cross-sectional shape using the bottom surface of the concave portion 13 as the base. At this stage, the number of dislocations in the nitride-based III-V compound semiconductor layer 15 propagated to the upper side is significantly decreased. Next, as shown in FIG. 21E, the nitride-based III-V compound semiconductor layer 15 is grown in the lateral direction. In this step, among dislocations propagated to the side surfaces of the nitride-based III-V compound semiconductor layer 15 having an isosceles triangle cross-sectional shape using the bottom surface of the concave portion 13 as the base, dislocations located at a lower position than the convex portions 12 extend to the side surfaces of the convex portions 12 in a direction parallel to the major surface of the substrate 11 and disappear, and dislocations located at a higher position than the convex portions 12 extend in a direction parallel to the major surface of the substrate 11 and are propagated to the side surfaces of the nitride-based III-V compound semiconductor layer 15 which is grown in the lateral direction. When the nitride-based III-V compound semiconductor layer 15 is further grown in the lateral direction, as shown in FIG. 21F, above the convex portion 12, the nitride-based III-V compound semiconductor layers 15 grown at two sides of the above convex portion 12 coalesce to each other, and the surfaces of the nitride-based III-V compound semiconductor layers 15 then form one flat surface parallel to the major surface of the substrate 11. The dislocations in the nitride-based III-V compound semiconductor layers 15 are bent toward the upper side (direction perpendicular to the major surface of the substrate 11) when the coalescence occurs above the convex portions 12, thereby forming threading dislocations.

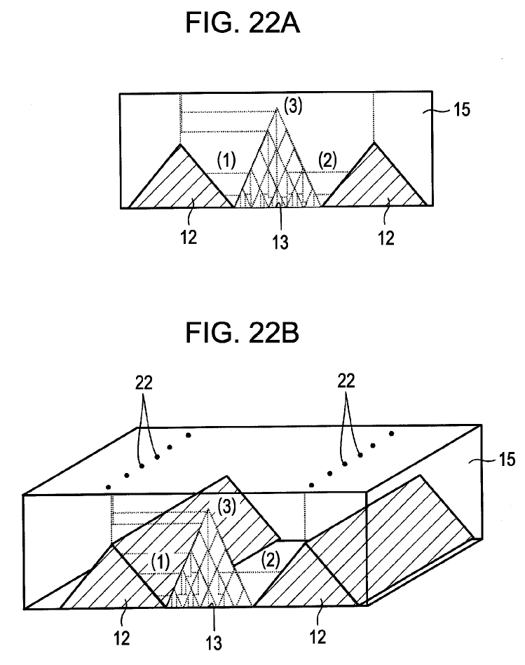

With reference to FIGS. 22A and 22B, the behavior of dislocation from the generation of the minute nuclei 14 to the lateral-direction growth of the nitride-based III-V compound semiconductor layer 15 will be again described. As shown in FIGS. 22A and 22B, in the process including the generation, the growth, and the coalescence of the minute nuclei 14, the dislocations generated from the interface with the substrate 11 are repeatedly bent in a direction (horizontal direction) parallel thereto and are bundled (dislocation (1)). In addition, the dislocations bent in the horizontal direction extend to the side surfaces of the convex portions 12 and disappear (dislocation (2)). Furthermore, the dislocations generated from the interface with the substrate 11 are bent only once and are propagated to the surface of the nitride-based III-V compound semiconductor layer 15 (dislocation (3)). Since the dislocations are bundled, and the dislocations bent in the horizontal direction extend to the side surfaces of the convex portions 12 and disappear, compared to the case in which the minute nuclei 14 are not generated, the nitride-based III-V compound semiconductor layer 15 having a small number of threading dislocations can be obtained.

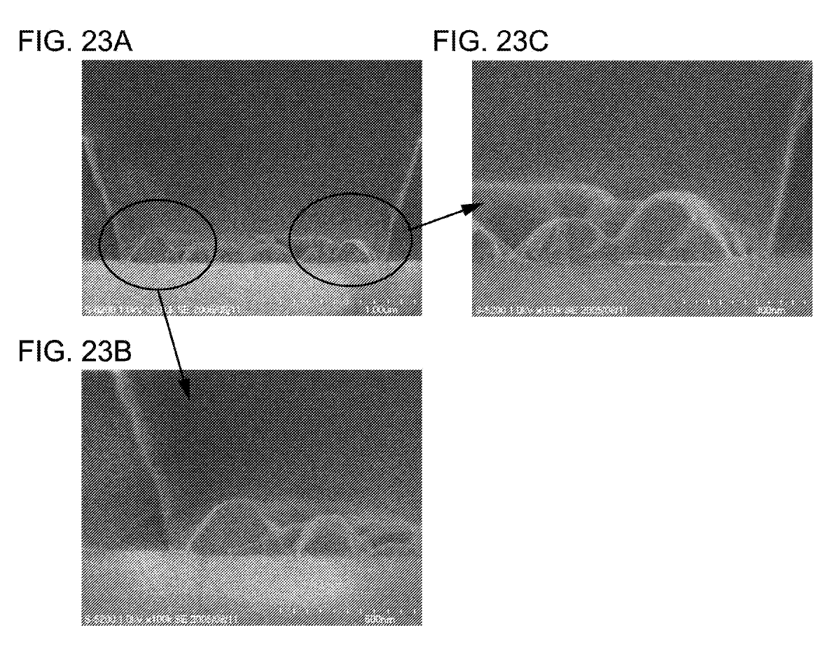

FIGS. 23A to 23C are each a cross-sectional TEM photograph showing the state in which the minute nuclei 14 are generated on the bottom surface of the concave portion 13 as shown in FIG. 21A. FIGS. 23B and 23C are each an enlarged cross-sectional TEM photograph showing the portion surrounded by an oval in FIG. 23A. From FIGS. 23A to 23C, it is clearly understood that the minute nuclei 14 are generated at the early growth stage.

Next, the difference in behavior of the dislocations generated in the nitride-based III-V compound semiconductor layer will be described between the case in which the minute nuclei 14 are generated at the early growth stage and the case in which the minute nuclei 14 are not generated.

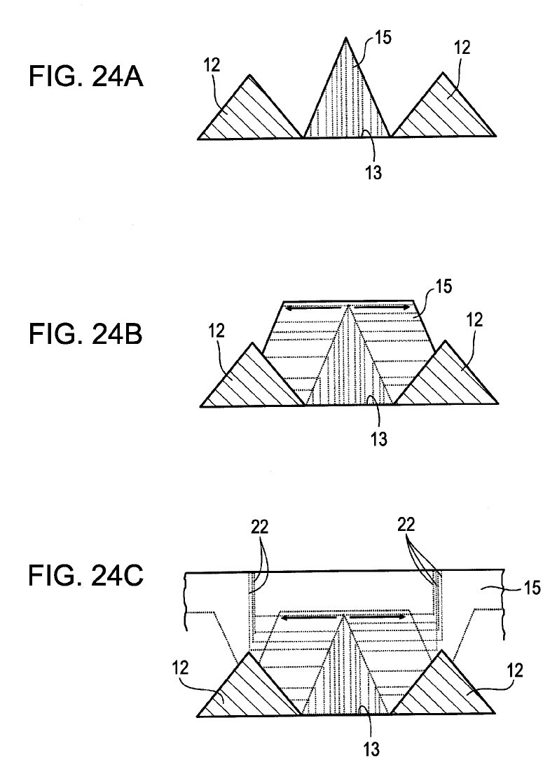

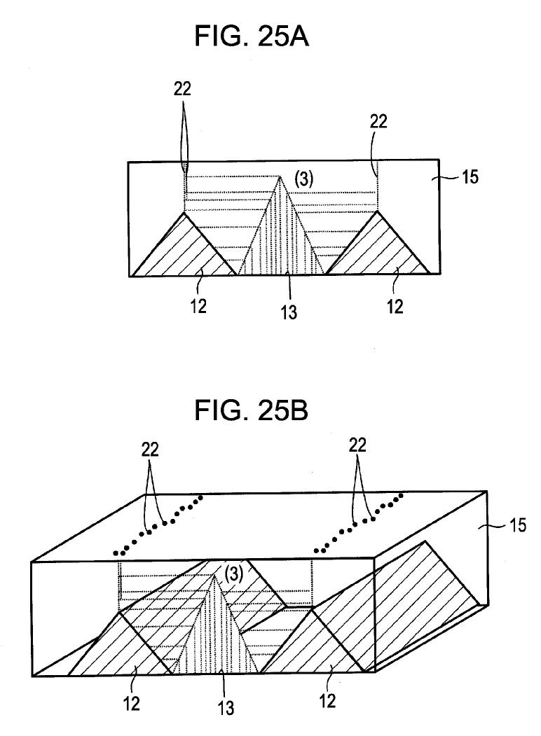

FIGS. 24A to 24C show the states corresponding to FIGS. 21D to 21F in which the minute nuclei 14 are not generated at the early growth stage of the nitride-based III-V compound semiconductor layer 15. As shown in FIG. 24A, in the case in which the minute nuclei 14 are not grown at the early growth stage, when the nitride-based III-V compound semiconductor layer 15 is grown to have an isosceles triangle cross-sectional shape using the bottom surface of the concave portion 13 as the base, dislocations extending from the interface with the bottom surface of the concave portion 13 to the upside are only present, and in general, this dislocation density is high as compared to that shown in FIG. 21D. When the growth is continued, as shown in FIG. 24B, among the dislocations propagated to the side surfaces of the nitride-based III-V compound semiconductor layer 15 having an isosceles triangle cross-sectional shape using the bottom surface of the concave portion 13 as the base, dislocations located at a lower position than the convex portion 12 extend to the side surfaces of the convex portions 12 and disappear, and dislocations located at a higher position than the convex portion 12 are propagated in a direction parallel to the major surface of the substrate 11 to the side surfaces of the nitride-based III-V compound semiconductor layer 15 which is grown in the lateral direction. When the nitride-based III-V compound semiconductor layer 15 is further grown in the lateral direction, as shown in FIG. 24C, above the convex portion 12, the nitride-based III-V compound semiconductor layers 15 grown at the two sides thereof coalesce to each other, and subsequently, the surfaces of the above nitride-based III-V compound semiconductor layers 15 form one flat surface parallel to the major surface of the substrate 11. Dislocations in the nitride-based III-V compound semiconductor layers 15 are bent upward when the coalescence occurs above the convex portion 12, thereby forming the threading dislocations 22. Although the density of the threading dislocations 22 is sufficiently low, it is high as compared to that of the case in which the minute nuclei 14 are generated on the bottom surface of the concave portion 13 at the early growth stage. The reason for this is that, as shown in FIGS. 25A and 25B, when the minute nuclei 14 are not generated, dislocations generated from the interface with the substrate 11 are bent only once in the horizontal direction when being propagated to the side surfaces of the isosceles triangle using the bottom surface of the concave portion 13 as the base. That is, in this case, the effect of bundling dislocations cannot be obtained during the process including the generation, the growth, and the coalescence of the minute nuclei 14.

As described above, according to this first embodiment, since a dielectric substance having a refractive index of 1.7 to 2.2 is used as a material for the convex portions 12, the light extraction efficiency of the light-emitting diode can be maximized. In addition, since spaces are not formed between the substrate 11 and the nitride-based III-V compound semiconductor layer 15, the decrease in light extraction efficiency caused by the spaces can be prevented. In addition, since the threading dislocations of the nitride-based III-V compound semiconductor layer 15 are concentrated in the vicinity of the central portion of the convex portion 12, and the dislocation density of the other portions is, for example, approximately 6×10⁷/cm², which is significantly decreased as compare to that in the case using a related concavo-convex processed substrate, the crystallinity of the nitride-based III-V compound semiconductor layer 15 and that of the nitride-based III-V compound semiconductor layers, such as the active layer 17, formed thereon are significantly improved, and the number of non-luminescent centers is significantly decreased, so that the internal quantum efficiency is improved. Accordingly, a nitride-based III-V compound semiconductor light-emitting diode having a significantly high luminous efficiency can be obtained.

In addition, epitaxial growth for manufacturing this nitride-based III-V compound semiconductor light-emitting diode may be performed only one time, and a growth mask is not used. Furthermore, since the convex portions 12 on the substrate 11 can be formed only by forming a dielectric film using a material for the convex portions 12 and then processing this dielectric film by an etching method, a powder blast method, a sand blast method, or the like, the substrate 11, such as a sapphire substrate, which is difficult to be processed, may not be processed, and the manufacturing process can be simplified; hence, as a result, the nitride-based III-V compound semiconductor light-emitting diode can be manufactured at a reasonable cost.

Next, a second embodiment of the present invention will be described.

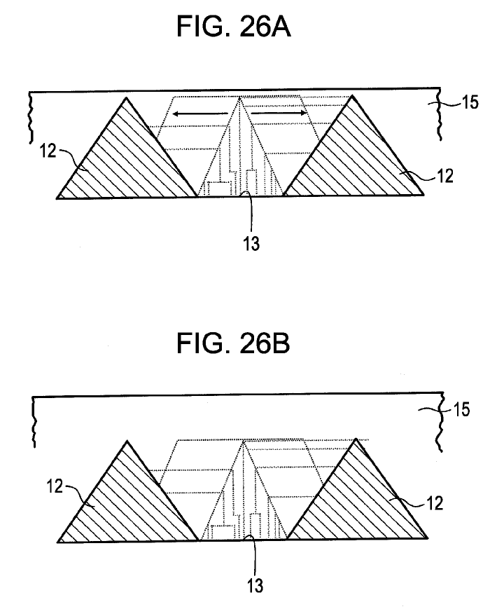

In this second embodiment, when the nitride-based III-V compound semiconductor layer 15 is grown to have an isosceles triangle cross-sectional shape using the bottom surface of the concave portion 13 as the base, the height of the convex portion 12 is selected so that the height of this nitride-based III-V compound semiconductor layer 15 is lower than that of the convex portion 12. As one example, in FIGS. 26A and 26B, the case in which the height of the nitride-based III-V compound semiconductor layer 15 is equal to that of the convex portion 12 is shown. By the configuration described above, all dislocations, which are generated from the interface with the substrate 11 and are propagated to the side surfaces of the nitride-based III-V compound semiconductor layer 15 having an isosceles triangle cross-sectional shape using the bottom surface of the concave portion 13 as the base, continue to extend to the side surfaces of the convex portions 12 in a direction parallel to the major surface of the substrate 11 and then disappear; hence, the number of the threading dislocations 22 propagated to the surface of the nitride-based III-V compound semiconductor layer 15 is dramatically decreased, and the dislocation density can be decreased to substantially zero.

The configuration other than that described above is similar to that in the first embodiment.

According to this second embodiment, since the nitride-based III-V compound semiconductor layer 15 having a threading dislocation density of substantially zero can be grown, a nitride-based III-V compound semiconductor substrate having substantially no dislocation can be obtained. In addition, for example, when the n-type nitride-based III-V compound semiconductor layer 16, the active layer 17, and the p-type nitride-based III-V compound semiconductor layer 18 are grown on this nitride-based III-V compound semiconductor substrate having substantially no dislocation, the dislocation densities of the layers described above can be significantly decreased, and as a result, a nitride-based III-V compound semiconductor light-emitting diode having significantly superior properties can be advantageously obtained. In addition, of course, advantages similar to those in the first embodiment can also be obtained.

Next, a third embodiment of the present invention will be described.

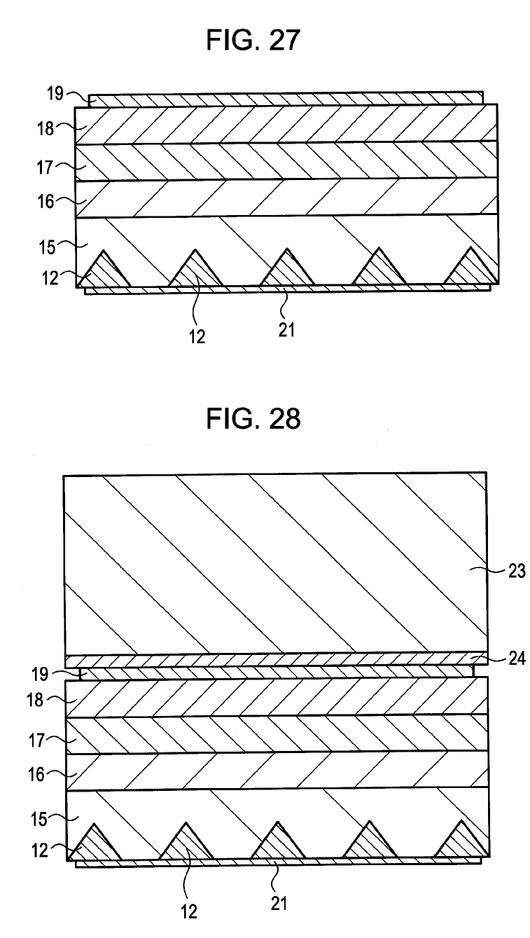

In this third embodiment, after the p-side electrode 19 is formed through the process similar to that in the first embodiment, without forming the mesa portion 20 in the n-type nitride-based III-V compound semiconductor layer 16, the active layer 17, and the p-type nitride-based III-V compound semiconductor layer 18, the substrate 11 is removed, so that the rear surface of the n-type nitride-based III-V compound semiconductor layer 15 is exposed. Subsequently, as shown in FIG. 27, the n-side electrode 21 is formed approximately over the entire rear surface of this nitride-based III-V compound semiconductor layer 15. In this case, when the p-type electrode 19 and the n-type electrode 21 are formed of a high-reflection electrode and a transparent electrode, respectively, light can be extracted outside through the n-side electrode 21 formed of the transparent electrode.

In this case, as the material for the convex portions 12, a dielectric substance having a refractive index of 1.0 to 2.3, in particular, such as CeO₂, HfO₂, Ta₂O₅, Y₂O₃, ZnO, ZrO₂, rhombic sulfur, LiTaO₃, LiNbO₃, AlON, SiO, Si₃N₄, Al₂O₃, BeO, MgO, SiO₂, LiF, CaF₂, MgF₂, NaF, AlF₃, CeF₃, LaF₃, or NdF₃, may be used and, for example, may be appropriately selected therefrom.

In addition, since the entire thickness of the light-emitting diode is significantly decreased by removing the substrate 11, in order to improve the mechanical strength, as shown in FIG. 28, a support substrate 23 may be bonded to the p-side electrode 19 with a metal electrode 24 provided therebetween by adhesion. As the support substrate 23, either a conductive or a non-conductive substrate may be used as long as it has a configuration to enable current to flow through the light-emitting diode via the metal electrode 24.

The configuration other than that described above is similar to that in the first embodiment.

According to this third embodiment, the flip chip type light-emitting diode obtained by removing the substrate 11 has advantages similar to those of the first embodiment. In addition, since the n-side electrode 21 is formed approximately over the entire rear surface of the nitride-based III-V compound semiconductor layer 15, the generation of a current crowing phenomenon during light-emitting diode operation can be prevented, and in particular, increase in output, increase in brightness, and increase in area of the light-emitting diode can be advantageously performed.

Next, a fourth embodiment of the present invention will be described.

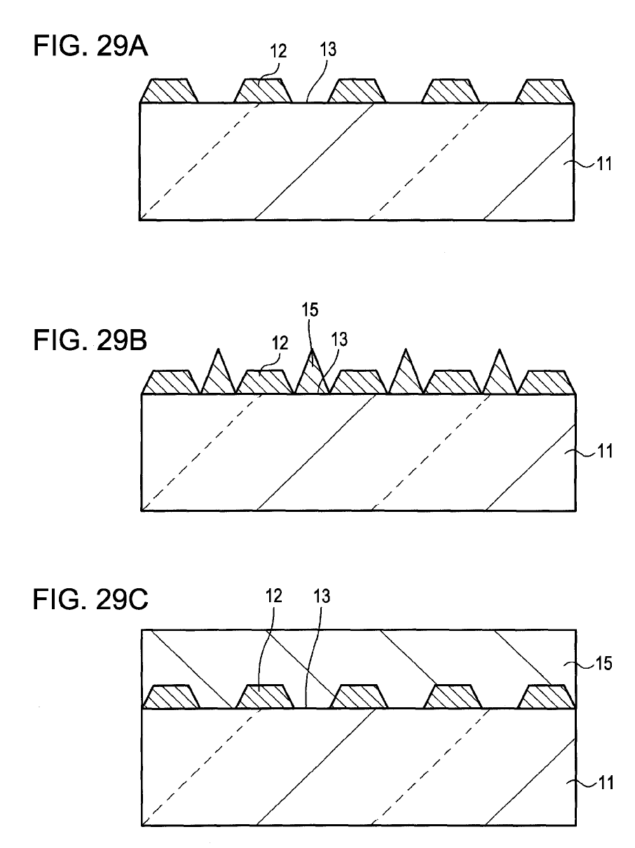

In this fourth embodiment, as shown in FIG. 29A, the convex portions 12 each having a trapezoid cross-sectional shape are periodically formed on the substrate 11 to form a predetermined plan matrix. Between the convex portions 12, the concave portions 13 are formed each having an inverted trapezoid cross-sectional shape.

Next, in a manner similar to that in the first embodiment, the nitride-based III-V compound semiconductor layer 15 is grown. In particular, through the process including the generation, the growth, and the coalescence of the minute nuclei 14 on the bottom surface of the concave portion 13, as shown in FIG. 29B, the nitride-based III-V compound semiconductor layer 15 having an isosceles triangle cross-sectional shape using the bottom surface of the concave portion 13 as the base is grown, and further through the lateral direction growth, as shown in FIG. 29C, the nitride-based III-V compound semiconductor layers 15 coalesce to each other to form one flat surface and to have a low threading dislocation density.

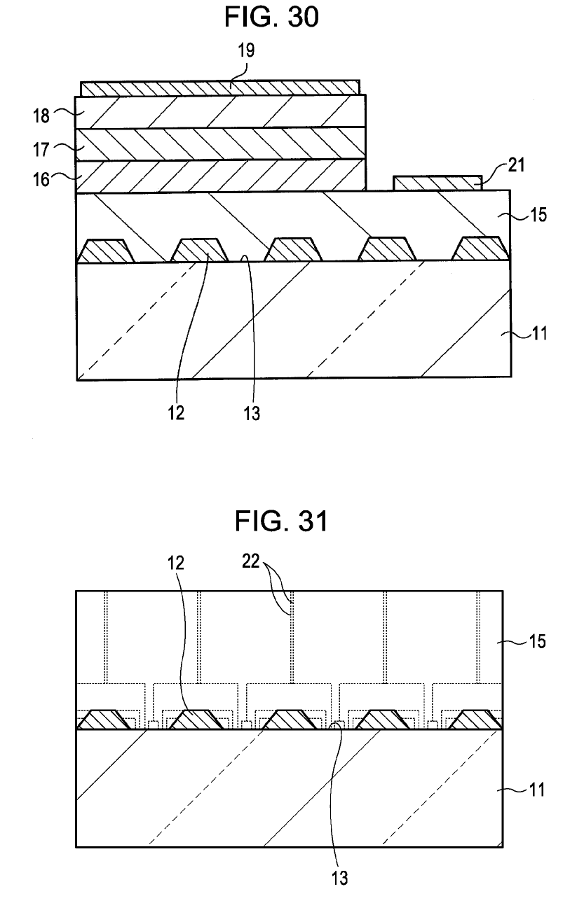

Subsequently, in a manner similar to that in the first embodiment, the steps are sequentially performed, and as shown in FIG. 30, an intended nitride-based III-V compound semiconductor light-emitting diode is manufactured.

The configuration other than that described above is similar to that described in the first embodiment.

In FIG. 31, the crystalline defect distribution in the nitride-based III-V compound semiconductor layer 15, which is measured by TEM, is schematically shown.

### EXAMPLE

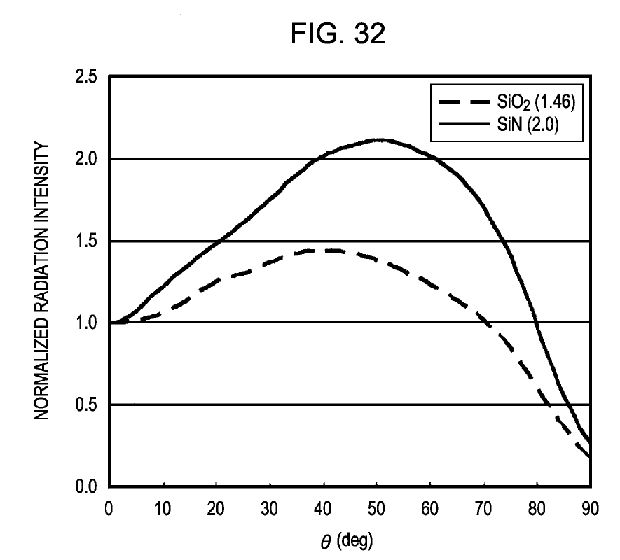

A light-emitting diode was formed by using Si₃N₄ having a refractive index of 2.0 as a dielectric substance forming the convex portions 12. As a comparative example, a light-emitting diode was formed by using SiO₂ having a refractive index of 1.46 as a dielectric substance forming the convex portions 12. The shape and the arrangement of the convex portions 12 were the same as those shown in FIG. 14. As the p-side electrode 19, a Ag electrode was used. The light-emitting wavelength X of the light-emitting diodes was 530 nm, and the distance D between the center (luminous point) of the active layer 17 having a multiquantum well structure and the reflection surface (interface between the p-type nitride-based III-V compound semiconductor layer 18 and the p-side electrode 19) was approximately 1.11 λn (n indicates the refractive index of the dielectric substance forming the convex portions 12). FIG. 32 shows far-field patterns of the two type of light-emitting diodes, which are normalized by the central light quantity. From FIG. 32, it was understood that the light-emitting diode using Si₃N₄ having a refractive index of 2.0 as a dielectric substance forming the convex portions 12 had high light-scattering properties, and that the light-emitting diode using SiO₂ having a refractive index of 1.46 as a dielectric substance forming the convex portions 12 had a high light-condensing property as compared to that of the above light-emitting diode. In addition, when the total radiant flux in this case was measured by an integrating sphere device (total radiant flux measurement device), the light-emitting diode using Si₃N₄ having a refractive index of 2.0 as a dielectric substance forming the convex portions 12 had a large total radiant flux. In Table 1, the results of the total radiant flux measurement of two samples of each light-emitting diode are shown. According to the results shown in Table 1, the light-emitting diode using Si₃N₄ having a refractive index of 2.0 as a dielectric substance forming the convex portions 12 had a larger radiant flux by approximately 10%.

TABLE 1

| Dielectric | | Radiant |
|---|---|---|
| substance forming | | flux |
| convex portions 12 | Sample No. | (mW) |
| SiO₂ | No. 1 | 11.37 |
| SiO₂ | No. 2 | 11.35 |
| Si₃N₄ | No. 1 | 12.56 |
| Si₃N₄ | No. 2 | 12.62 |

### According to this fourth embodiment, advantages similar to those obtained in the first embodiment can be obtained.

Next, a fifth embodiment according to the present invention will be described.

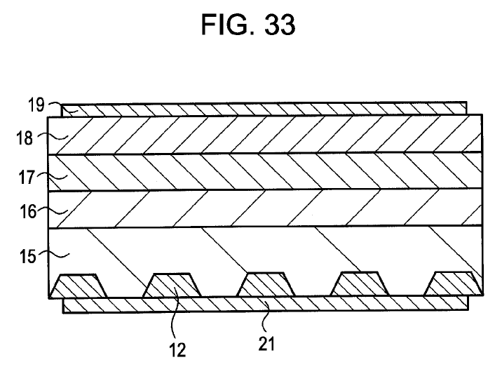

In this fifth embodiment, after the p-side electrode 19 is formed through the process similar to that in the fourth embodiment, without forming the mesa portion 20 in the n-type nitride-based III-V compound semiconductor layer 16, the active layer 17, and the p-type nitride-based III-V compound semiconductor layer 18, the substrate 11 is removed, so that the rear surface of the n-type nitride-based III-V compound semiconductor layer 15 is exposed. Subsequently, as shown in FIG. 33, the n-side electrode 21 is formed on the rear surface of this nitride-based III-V compound semiconductor layer 15. In this case, when the p-type electrode 19 and the n-type electrode 21 are formed of a high-reflection electrode and a transparent electrode, respectively, light can be extracted outside through the n-side electrode 21 formed of the transparent electrode.

In this case, as the material for the convex portions 12, a dielectric substance having a refractive index of 1.0 to 2.3 may be used as is the case of the third embodiment.

In addition, since the entire thickness of the light-emitting diode is significantly decreased by removing the substrate 11, in order to improve the mechanical strength, as is the case shown in FIG. 28, the support substrate 23 may be bonded to the p-side electrode 19 via the metal electrode 24 provided therebetween by adhesion.

The configuration other than that described above is similar to that in the fourth embodiment.

According to this fifth embodiment, advantages similar to those obtained in the third embodiment can be obtained.

Next, a sixth embodiment according to the present invention will be described.

In this sixth embodiment, after the mesa portion 20 is formed through the process similar to that in the fourth embodiment, the substrate 11 is removed, so that the rear surface of the n-type nitride-based III-V compound semiconductor layer 15 is exposed. The planar shape and arrangement of the convex portions 12 are the same as those shown in FIG. 14. Subsequently, on part of the nitride-based III-V compound semiconductor layer 15 adjacent to the mesa portion 20, an electrode 25 is formed.

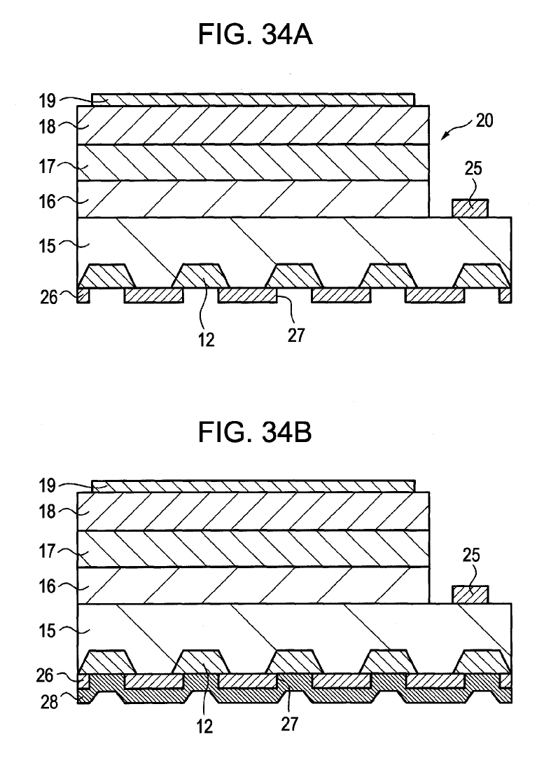

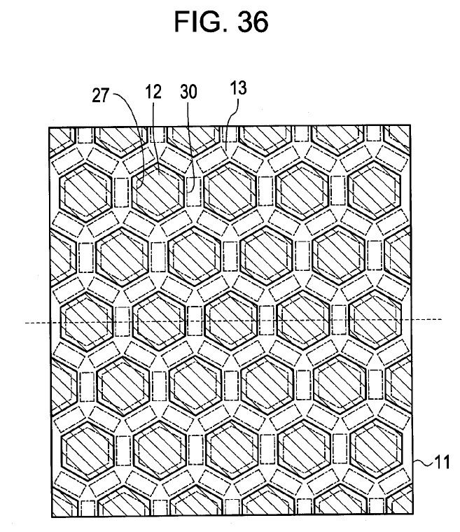

Next, as shown in FIG. 34A, after an insulating film 26 such as a SiO₂ film is formed on the rear surface of this nitride-based III-V compound semiconductor layer 15, parts of this insulating film 26 corresponding to the convex portions 12 are removed by etching to form contact holes 27. In FIG. 36, one example of the planar shape of this contact hole 27 is shown.

Next, as shown in FIG. 34B, a transparent electrode 28 made of ITO or the like is formed on this insulating film 26 and the entire surfaces of the convex portions 12 exposed through the contact holes 27. This transparent electrode is connected to the convex portions 12 via the contact holes 27. This transparent electrode 28 is electrically separated from the nitride-based III-V compound semiconductor layer 15 by the insulating film 26.

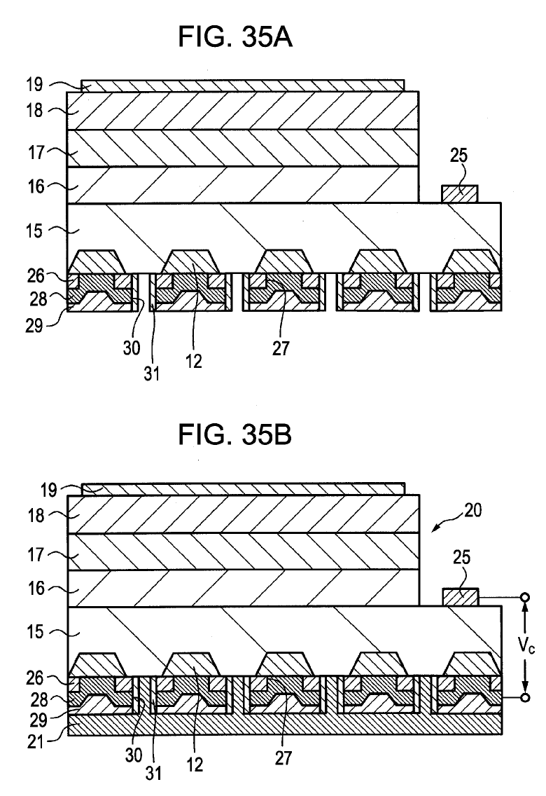

Next, as shown in FIG. 35A, after an insulating film 29 made of a SiO₂ film or the like is formed on the entire surface of this transparent electrode 28, parts of this insulating film 29, the transparent electrode 28, and the insulating film 26, which correspond to parts of the nitride-based III-V compound semiconductor layer 15 located between the convex portions 12, are removed by etching to form contact holes 30. In FIG. 36, one example of the planar shape of this contact hole 30 is shown. Next, on the inside wall of this contact hole 30, an insulating film 31, such as a SiO₂ film, is formed.

Subsequently, as shown in FIG. 35B, the n-side electrode 21, that is, a transparent electrode made of ITO or the like, is formed on this insulating film 29 so as to be electrically connected to the nitride-based III-V compound semiconductor layer 15 via the contact holes 30. This n-side electrode 21 is electrically separated from the transparent electrode 28 by the insulating films 26, 29, and 31.

In the case described above, as the material for the convex portions 12, a dielectric substance capable of changing the refractive index by applying a voltage, in particular, such as lithium niobate, lithium tantalate, or lanthanum-doped lead zirconate titanate, may be used, and for example, may be appropriately selected therefrom.

According to this sixth embodiment, as shown in FIG. 35B, by applying a voltage Vc between the electrode 25 and the electrode 28, the refractive index of the convex portion 12 can be changed, and hence the far-field pattern of the light-emitting diode can be controlled. In particular, when the refractive index of the convex portions 12 is set to 1.0 to 2.3, advantages similar to those obtained in the fourth embodiment can be obtained.

Next, a seventh embodiment of the present invention will be described.

In this seventh embodiment, a process similar to that in the first embodiment was performed until the step of forming the p-side electrode 19, and steps thereafter are different from those in the first embodiment. In this embodiment, a technique is preferably applied to this p-side electrode 19 in which a layer containing Pd is provided to prevent diffusion of an electrode material (such as Ag), and/or in order to prevent the generation of defects caused, for example, by stress, heat, and/or diffusion of Au or Sn to the p-side electrode 19 from a layer (solder layer, bump, or the like) which contains Au or Sn and which is formed at an upper side, a layer composed of a high melting point metal, such as Ti, W, Cr, or an alloy thereof, or composed of a metal nitride thereof (TiN, WN, TiWN, CrN, or the like) is further formed on the above Pd-containing layer so as to be used as an amorphous barrier metal layer having no grain boundaries. As for the technique providing a layer containing Pd, a Pd interstitial layer is known, for example, in a metal plating technique, and the above barrier layer material is well known, for example, in an Al wiring technique or a Ag wiring technique for Si-based electronic devices.

In addition, in this embodiment, in order to protect the p-side electrode 19 which is directly in contact with the p-type nitride-based III-V compound semiconductor layer 18 and which has inferior resistance against thermal stress, an example is disclosed in which a high melting point metal, such as Ti, W, Cr, or an alloy thereof, or a nitride of the aforementioned metal is provided to form a protective layer. However, since this protective layer itself can be used as an electrode in direct contact with the p-type nitride-based III-V compound semiconductor layer 18 and has stress resistance and an adhesion enhancing force, besides the electrode at the p-type nitride-based III-V compound semiconductor layer 18 side, it may also be used as an n-side electrode for the first layer instead of a Ti/Pt/Au electrode which has been used as the n-side electrode 21 in contact with the n-type nitride-based III-V compound semiconductor layer 15. As a method using an adhesion enhancing force, for example, a substrate bonding technique may be used at the p side and/or the n side to enhance a bonding strength of a metal-metal bonding portion, a metal-dielectric substance bonding portion, or the like. As one particular example for obtaining stress resistance and/or adhesion enhancing force, when an outermost surface of the p-side electrode 19 composed of a monolayer metal film or a multilayer metal film is formed of Au, after a high melting point metal film of Ti, W, Cr, or an alloy thereof, or a nitride of the aforementioned metal is formed on a conductive support substrate, a Au film is further formed on the film described above, and this Au film can be bonded to the p-side electrode 19.

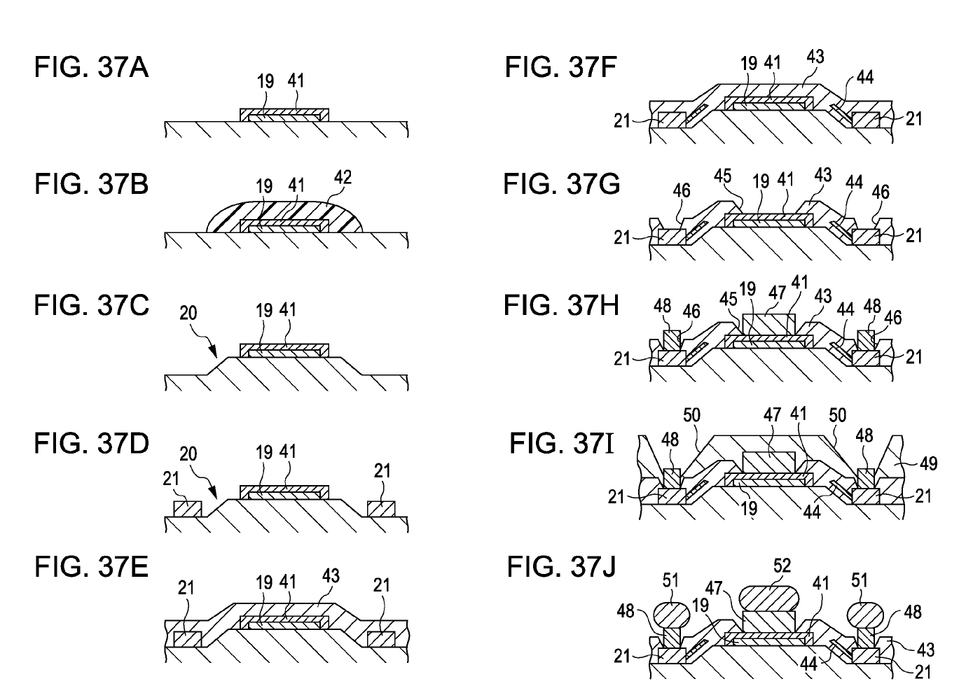

That is, in this seventh embodiment, as shown in FIG. 37A, after the p-side electrode 19 is formed, a Ni film 41 is formed so as to cover this p-side electrode 19 by a lift-off method or the like. Next, although not shown in the figure, for example, after a Pd film is formed so as to cover the Ni film 41, a metal nitride film, such as a film made of TiN, WN, TiWN, CrN, or the like, is formed so as to cover this Pd film, and furthermore, whenever necessary, a film of Ti, W, Mo, Cr, alloy thereof, or the like is formed so as to cover the above metal nitride film. However, instead of forming the Ni film 41, the following process may also be performed. That is, after a Pd film is formed to cover the p-side electrode 19, a film of TiN, WN, TiWN, CrN, or the like is formed so as to cover the Pd film, and furthermore, whenever necessary, a film of Ti, W, Mo, Cr, an alloy thereof, or the like is formed so as to cover the above metal nitride film.

Next, as shown in FIG. 37B, by lithography, a resist pattern 42 having a predetermined shape is formed so as to cover the Ni film 41 and the Pd film or the like provided thereon.

Next, as shown in FIG. 37C, etching is performed by an RIE method or the like using the resist pattern 42 as a mask so that the mesa portion 20 is formed to have a trapezoid cross-sectional shape. The angle formed between the inclined surface of the mesa portion 20 and the major surface of the substrate 11 is set, for example, to approximately 35°. On the inclined surface of this mesa portion 20, a λ/4 dielectric film (λ: light-emitting wavelength) is formed whenever necessary.

Subsequently, as shown in FIG. 37D, the n-side electrode 21 is formed on the n-type nitride-based III-V compound semiconductor layer 15.

Next, as shown in FIG. 37E, as a passivation film, a SiO₂ film 43 is formed over the entire surface of the substrate. When the adhesion to an underlying layer, durability, and corrosion resistance during the process are taken into consideration, instead of the SiO₂ film 43, a SiN film or a SiON film may be used.

Subsequently, as shown in FIG. 37F, after this SiO₂ film 43 is etched back so as to decrease the thickness thereof, Al film 44 is formed as a reflection film on the SiO₂ film 43 on the inclined surface of the mesa portion 20. This Al film 44 is provided to improve the light extraction efficiency by reflecting light generated from the active layer to the substrate side. One end of this Al film 44 is formed so as to be in contact with the n-side electrode 21. The reason for this is to increase reflection of light without forming a space between the Al film 44 and the n-side electrode 21. Then, the SiO₂ film 43 is again formed so as to obtain a passivation film having a sufficient thickness as the passivation film.

Next, as shown in FIG. 37G, parts of the SiO₂ film 43 located on the Ni film 41 and the n-side electrode 21 are removed by etching to form openings 45 and 46, so that the Ni film 41 and the n-side electrode 21 are exposed therethrough.

Next, as shown in FIG. 37H, a pad electrode 47 is formed on the Ni film 41 exposed through the opening 45, and in addition, a pad electrode 48 is formed on the n-side electrode 21 exposed through the opening 46.

Subsequently, as shown in FIG. 37I, after a bump mask material 49 is formed over the entire surface of the substrate, part of the bump mask material 49 located on the pad electrode 48 is removed by etching to form an opening 50, so that the pad electrode 48 is exposed therethrough.

Next, as shown in FIG. 37J, an Au bump 51 is formed on the pad electrode 48 using the bump mask material 49. Then, the bump mask material 49 is removed. After a bump mask material (not shown) is again formed over the entire surface of the substrate, part of this bump mask material located on the pad electrode 47 is removed by etching to form an opening, so that the pad electrode 47 is exposed therethrough. Next, an Au bump 52 is formed on the pad electrode 47.

Next, whenever necessary, after the rear surface of the substrate 11 on which the light-emitting diode structure is formed as described above is polished or lapped to decrease the thickness, this substrate 11 is scribed to form bars. Subsequently, this bar is scribed to form chips.

The electrode lamination structure of the light-emitting diode described with reference to FIGS. 37A to 37J is merely one example. In particular, when the electrode is formed of layers laminated to each other, while suppression of the generation of stress caused by the difference in coefficient of thermal expansion between metal layers concomitant with an increase in element temperature, and suppression of the diffusion between the metal layers are taken into consideration, it is particularly important to intend to obtain improvement in adhesion between the p-side electrode 19 made of a Ag electrode or the like and another metal layer, improvement in stress durability, improvement in crack resistance, decrease in contact resistance, and higher reflectance by quality maintenance of a Ag electrode and the like. Hence, whenever necessary, for example, the above Al wiring technique for Si-based electronic devices may also be used.

Next, an eighth embodiment of the present invention will be described.

In this eighth embodiment, the case will be described in which a light-emitting diode backlight is manufactured by using a red light-emitting diode (such as an AlGaInP-based light-emitting diode), which is separately prepared, together with a blue light-emitting diode and a green light-emitting diode obtained by the method according to the first embodiment.

After blue light-emitting diode structures are formed on the substrate 11 by the method according to the first embodiment, and bumps (not shown) are then formed on the corresponding p-side electrodes 19 and n-side electrodes 21, the substrate 11 is scribed to form chips, so that flip chip type blue light-emitting diodes are obtained. In a manner similar to that described above, flip chip type green light-emitting diodes are obtained. In addition, diode structures are formed by laminating AlGaInP-based semiconductor layers on an n-type GaAs substrate, followed by forming p-side electrodes on the laminate, so that chip-type AlGaInP-based light-emitting diodes are each obtained as a red light-emitting diode.

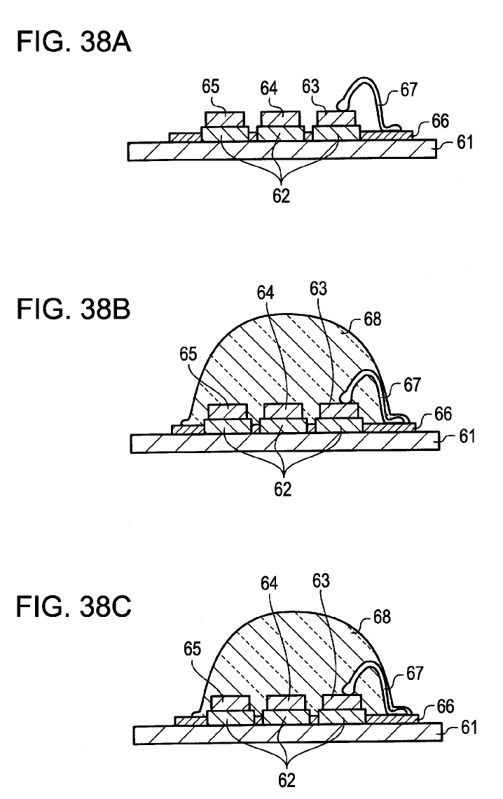

Subsequently, the red light-emitting diode chip, the green light-emitting diode chip, and the blue light-emitting diode chip are mounted on respective submounts made of AlN or the like and are then mounted at predetermined positions on a substrate, such as an Al substrate, so that the submounts are brought into contact with the substrate. This state is shown in FIG. 38A. In FIG. 38A, reference numeral 61 indicates the substrate, reference numeral 62 indicates the submount, reference numeral 63 indicates the red light-emitting diode chip, reference numeral 64 indicates the green light-emitting diode chip, and reference numeral 65 indicates the blue light-emitting diode chip. The chip sizes of the red light-emitting diode chip 63, the green light-emitting diode chip 64, and the blue light-emitting diode chip 65 are, for example, 350 μm square. In this embodiment, the red light-emitting diode chip 63 is mounted so that its n-side electrode is placed on the submount 62, and the green light-emitting diode chip 64 and the blue light-emitting diode chip 65 are mounted so that their p-side electrodes and n-side electrodes are provided on the respective submounts 62 via bumps. On the submount 62 on which the red light-emitting diode chip 63 is mounted, an extraction electrode (not shown) having a predetermined pattern shape is formed for the n-side electrode, and the n-side electrode of the red light-emitting diode chip 63 is mounted on a predetermined portion of this extraction electrode. A wire 67 is bonded to a p-side electrode of this red light-emitting diode chip 63 and a predetermined pad electrode 66 provided on the substrate 61 so as to connect therebetween, and in addition, a wire (not shown) is bonded to one end of the extraction electrode and another pad electrode provided on the substrate 61 so as to connect therebetween. On the submount 62 on which the green light-emitting diode chip 64 is mounted, an extraction electrode for the p-side electrode and an extraction electrode for the n-side electrode (both extraction electrodes are not shown in the figure) are formed to have respective predetermined pattern shapes, and the p-side electrode and the n-side electrode of the green light-emitting diode chip 64 are mounted on predetermined portions of the extraction electrodes for the p-side electrode and the n-side electrode via respective bumps formed thereon. In addition, a wire (not shown) is bonded to one end of the extraction electrode for the p-side electrode of this green light-emitting diode chip 64 and a pad electrode provided on the substrate 61 so as to connect therebetween, and a wire (not shown) is boned to one end of the extraction electrode for the n-side electrode and a pad electrode provided on the substrate 61 so as to connect therebetween. The blue light-emitting diode chip 65 is also mounted in a manner similar to that described above.

However, without using the submounts 62, the red light-emitting diode chip 63, the green light-emitting diode chip 64, and the blue light-emitting diode chip 65 may be directly mounted on an arbitrary printed circuit board having heat dissipation properties, or on a plate or an internal or an external wall (such as an internal wall of a chassis) having a printed circuit board function, and by this direct mounting, the cost of the light-emitting diode backlight or the cost of the entire panel can be reduced.

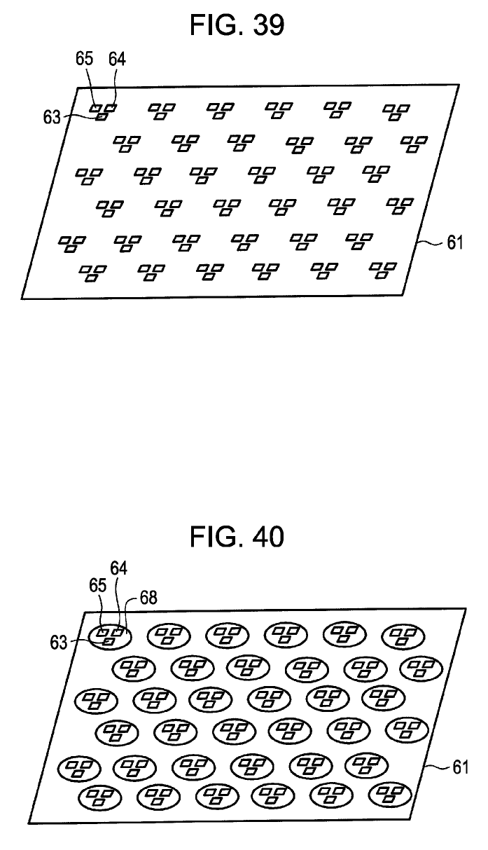

As described above, the red light-emitting diode chip 63, the green light-emitting diode chip 64, and the blue light-emitting diode chip 65 are used as one unit (cell), and a necessary number of the cells is disposed on the substrate 61 in a predetermined pattern. One pattern example is shown in FIG. 39. Next, as shown in FIG. 38B, potting is performed using a transparent resin 68 so as to cover the one unit. Then, a curing treatment is performed for the transparent resin 68. By this curing treatment, the transparent resin 68 is solidified, and concomitant with this solidification, the resin 68 slightly contracts (FIG. 38C). Accordingly, as shown in FIG. 40, cells each containing the red light-emitting diode chip 63, the green light-emitting diode chip 64, and the blue light-emitting diode chip 65 as one unit are arranged on the substrate 61 in an array matrix, so that a light-emitting diode backlight is obtained. In this case, since the transparent resin 68 is in contact with the rear surface of the substrate 11 of the green light-emitting diode chip 64, and that of the blue light-emitting diode chip 65, the difference in refractive index is decreased as compared to the case in which the rear surface of the substrate 11 is directly in contact with air, and the degree of reflection of light, which is to be emitted outside through the substrate 11, at the rear surface of this substrate 11 is decreased; hence, the light extraction efficiency is improved, and as a result, the luminous efficiency is improved.

This light-emitting diode backlight is preferably used, for example, for a backlight for liquid crystal panels.

Next, a ninth embodiment of the present invention will be described.

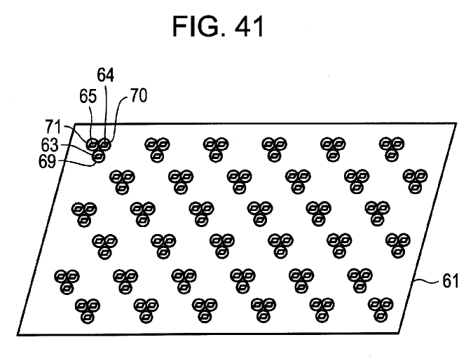

In this ninth embodiment, as is the eighth embodiment, after a necessary number of cells each containing the red light-emitting diode chip 63, the green light-emitting diode chip 64, and the blue light-emitting diode chip 65 is disposed on the substrate 61 in a predetermined pattern, as shown in FIG. 41, potting is performed so as to cover the red light-emitting diode 63 using a transparent resin 69 suitable therefor, potting is performed so as to cover the green light-emitting diode 64 using a transparent resin 70 suitable therefor, and potting is performed so as to cover the blue light-emitting diode 65 using a transparent resin 71 suitable therefor. Then, a curing treatment is performed for the transparent resins 69 to 71. By this curing treatment, the transparent resins 69 to 71 are solidified, and concomitant with this solidification, the resins slightly contract. Accordingly, a light-emitting diode backlight is obtained in which cells each containing the red light-emitting diode chip 63, the green light-emitting diode chip 64, and the blue light-emitting diode chip 65 as one unit are arranged on the substrate 61 in an array matrix. In this case, since the transparent resins 70 and 71 are in contact with the rear surface of the substrate 11 of the green light-emitting diode chip 64 and that of the blue light-emitting diode chip 65, respectively, the difference in refractive index is decreased as compared to the case in which the rear surface of the substrate 11 is directly in contact with air, and the degree of reflection of light, which is to be emitted outside through the substrate 11, at the rear surface of this substrate 11 is decreased; hence, the light extraction efficiency is improved, and as a result, the luminous efficiency is improved.

This light-emitting diode backlight is preferably used, for example, for a backlight for liquid crystal panels.

Next, a tenth embodiment of the present invention will be described.

In this tenth embodiment, the case will be described in which a light source cell unit is manufactured by using a red light-emitting diode, which is separately prepared, together with a blue light-emitting diode and a green light-emitting diode obtained by the method according to the first embodiment.

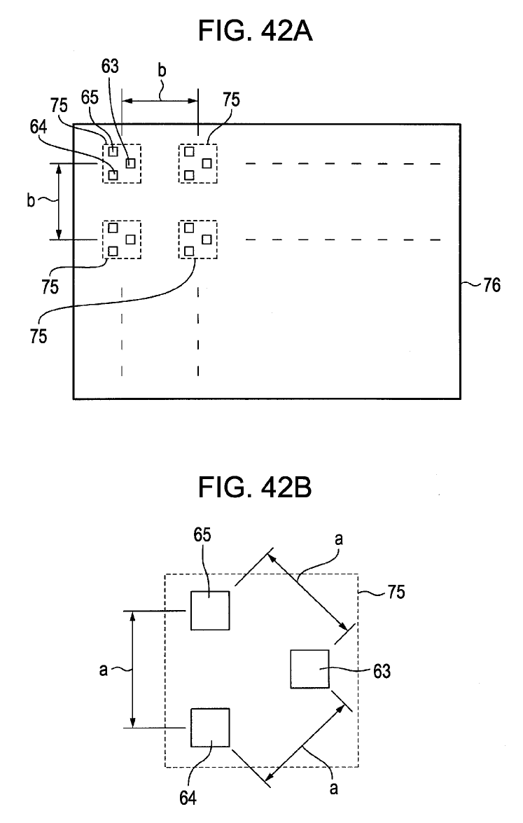

As shown in FIG. 42A, in the tenth embodiment, as is the case of the eighth embodiment, a necessary number of cells 75 is arranged in a predetermined pattern on a printed circuit board 76, the cells 75 each containing at least one red light-emitting diode chip 63, at least one green light-emitting diode chip 64, and at least one blue light-emitting diode chip 65, the above light-emitting diode chips being arranged in a predetermined pattern in each cell. In this example, in each cell 75, the red light-emitting diode chip 63, the green light-emitting diode chip 64, and the blue light-emitting diode chip 65 are included and are located at the apexes of a regular triangle. FIG. 42B is an enlarged view of the cell 75. In the cell 75, the distance a between the two of the red light-emitting diode chip 63, the green light-emitting diode chip 64, and the blue light-emitting diode chip 65 is, for example, 4 mm; however, it is not limited thereto. The distance b between adjacent cells 75 is, for example, 30 mm; however, it is not limited thereto. As the printed circuit board 76, for example, an FR4 (abbreviation of Flame Retardant Type 4) substrate, a metal core substrate, or a flexible wire substrate may be used, and in addition, another printed circuit board having heat dissipation properties may also be used; however, it is not limited thereto. As is the case of the eighth embodiment, potting is performed using the transparent resin 68 so as to cover each cell 75, or alternatively, as is the case of the ninth embodiment, potting is performed using the transparent resin 69 so as to cover the red light-emitting diode chip 63, potting is performed using a transparent resin 70 so as to cover the green light-emitting diode chip 64, and potting is performed using a transparent resin 71 so as to cover the blue light-emitting diode chip 65. Accordingly, the light source cell unit is obtained in which the cells 75 each containing the red light-emitting diode chip 63, the green light-emitting diode chip 64, and the blue light-emitting diode chip 65 are arranged on the printed circuit board 76.

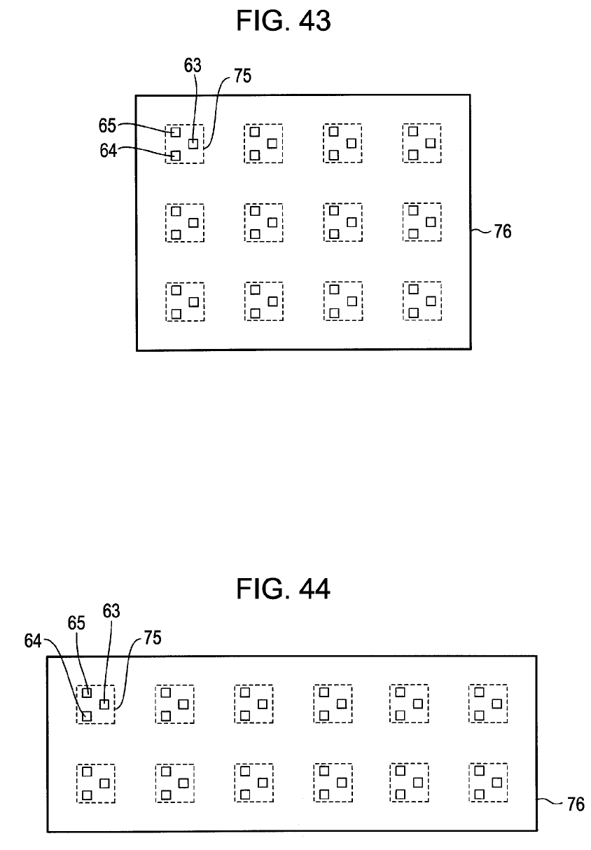

Concrete examples of the arrangement of the cells 75 on the printed circuit board 76 are shown in FIGS. 43 and 44; however, the arrangement is not limited thereto. In the example shown in FIG. 43, the cells 75 are disposed in a two-dimensional array of 4 by 3, and in the example shown in FIG. 44, the cells 75 are disposed in a two-dimensional array of 6 by 2.

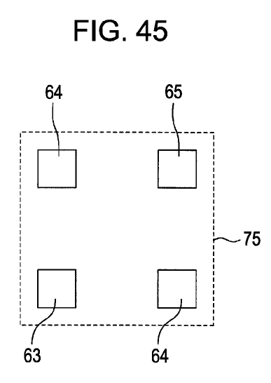

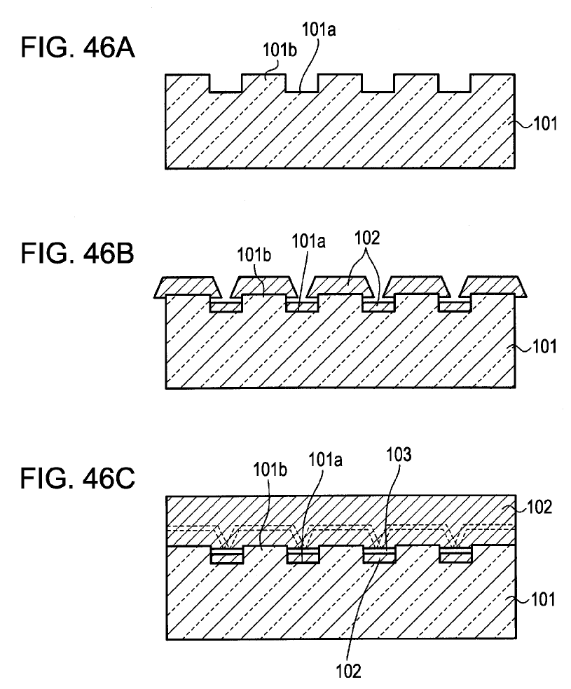

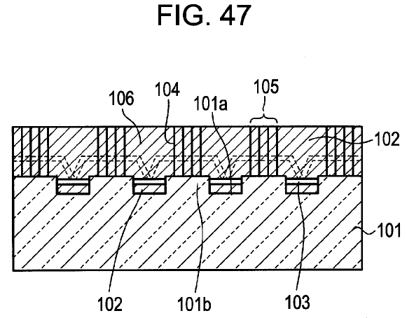

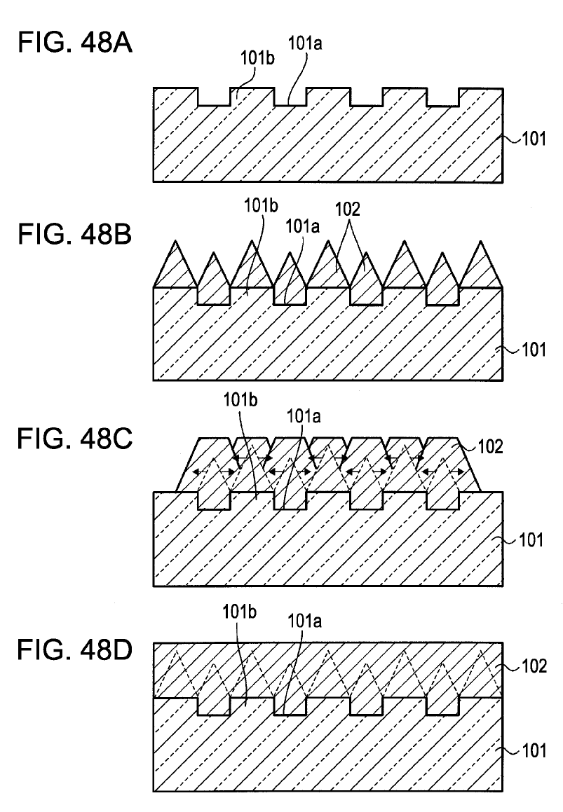

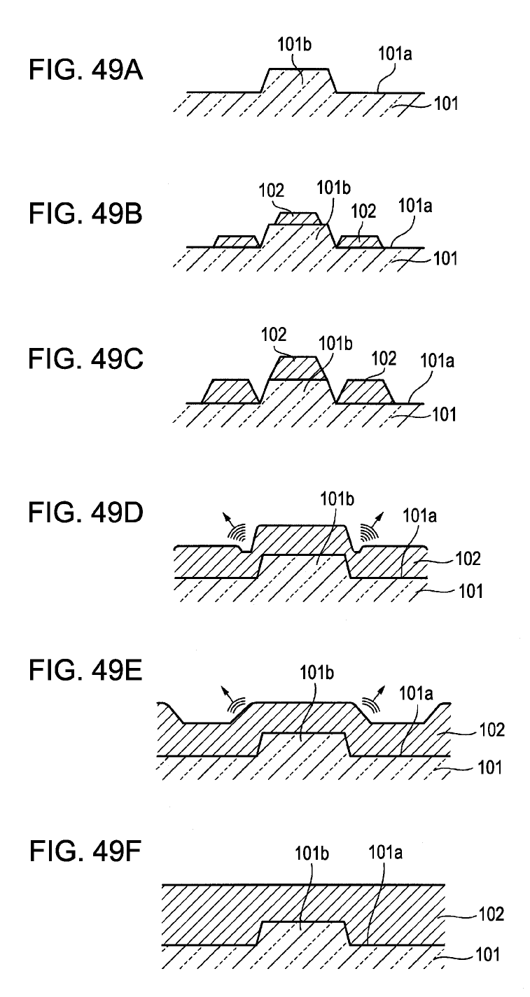

In FIG. 45, another structure example of the cells 75 is shown. In this example, the cell 75 includes one red light-emitting diode chip 63, two green light-emitting diode chips 64, and one blue light-emitting diode chip 65, and these chips are disposed, for example, at the apexes of a regular tetragon. The two green light-emitting diode chips 64 are disposed at two ends of one diagonal line of the regular tetragon, and the red light-emitting diode chip 63 and the blue light-emitting diode 65 are disposed at the two end of the other diagonal line of the regular tetragon.

When at least one light source cell unit described above is disposed, a light-emitting diode backlight can be obtained which is preferably used, for example, as a backlight of liquid crystal panels.

Although the pad electrode portion, the wiring portion, and the like on the printed circuit substrate 76 are generally formed from Au, after those mentioned above are all or partly formed from a high melting point metal, such as Ti, W, Cr, or an alloy thereof, having durability and an adhesion enhancing force or from a nitride of the aforementioned metal, Au may then be formed thereon. The pad electrode portion, the wiring portion, and the like described above may be formed, for example, by electroplating, electroless plating, vacuum deposition (flash deposition), or sputtering using the materials mentioned above. Alternatively, after the pad electrode portion, the wiring portion, and the like are formed from Au, films may be formed thereon using the materials mentioned above. In addition, for example, the following may also be performed. That is, after the pad electrode portion, the wiring portion, and the like are formed from a high melting point metal, such as Ti, W, Cr, or an alloy thereof, and are then nitrided, a high melting point metal, such as Ti, W, Cr, or an alloy thereof, is again deposited thereon so that the surface is placed in the state before nitridation, and on the surface thereof, the light-emitting diode chips 63 to 65 may be die-bonded from TiW electrode or Au electrode sides with films of Ti, W, Cr, Au, or the like interposed therebetween, whenever necessary.

In addition, when a protective chip (circuit), a base-opened transistor element (circuit), a trigger diode element (circuit), a negative resistance element (circuit), and the like are mounted which are to be connected to the light-emitting diode chips 63 to 65 mounted on the printed circuit board 76, in order to improve the reliability, such as adhesion strength and heat-stress resistance, of the light source cell, the above electrode structure using a high melting point metal such as Ti, W, Cr, or an alloy thereof, or a nitride of the aforementioned metal may also be used.

In addition, on areas on the printed circuit board 76 other than those on which the transparent resins 68 to 71 are potted, a white resist may be applied as thick as possible so as to suppress light emitted from the light-emitting diode chips 63 to 65 from being absorbed by the printed circuit board 76.

Heretofore, although the embodiments of the present invention are particularly described, the present invention is not limited to the above embodiments, and various modifications may be made without departing from the sprit and the scope of the present invention.

For example, the numeric values, materials, structures, shapes, substrates, raw materials, processes, directions of the convex portions 12 and the concave portions 13, and the like of the first to the tenth embodiments are described by way of example, and whenever necessary, numeric values, materials, structures, shapes, substrates, raw materials, processes, and the like different from those described above may be used.

In particular, for example, in the above first to tenth embodiments, the conductance of the p-type conductive layer and that of the n-type conductive layer may be set opposite to each other.

Furthermore, whenever necessary, at least two of the first to the tenth embodiments may be used in combination.

It should be understood by those skilled in the art that various modifications, combinations, sub-combinations and alterations may occur depending on design requirements and other factors insofar as they are within the scope of the appended claims or the equivalents thereof.

What is claimed is:

1. A method for manufacturing a light-emitting diode, comprising the steps of:
preparing a substrate provided with convex portions on one major surface, the convex portions being formed from a dielectric substance which is different from the substrate and which has a refractive index of 1.7 to 2.2;
growing a first nitride-based III-V compound semiconductor layer in a concave portion on the substrate through the state of a triangle cross-sectional shape using the bottom surface of the concave portion as the base;
growing a second nitride-based III-V compound semiconductor layer on the substrate from the first nitride-based III-V compound semiconductor layer in a lateral direction; and
sequentially growing, on the second nitride-based III-V compound semiconductor layer, a first conductive type third nitride-based III-V compound semiconductor layer, an active layer, and a second conductive type fourth nitride-based III-V compound semiconductor layer.

2. A light-emitting diode comprising:
a substrate provided with convex portions on one major surface, the convex portions being composed of a dielectric substance which is different from the substrate and which has a refractive index of 1.7 to 2.2;
a fifth nitride-based III-V compound semiconductor layer grown on the substrate without forming a space in a concave portion on the substrate; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

3. A method for manufacturing a light-emitting diode, comprising the steps of:
preparing a substrate provided with convex portions on one major surface, the convex portions being formed from a dielectric substance which is different from the substrate and which has a refractive index of 1.0 to 2.3;
growing a first nitride-based III-V compound semiconductor layer in a concave portion on the substrate through the state of a triangle cross-sectional shape using the bottom surface of the concave portion as the base;
growing a second nitride-based III-V compound semiconductor layer on the substrate from the first nitride-based III-V compound semiconductor layer in a lateral direction;
sequentially growing, on the second nitride-based III-V compound semiconductor layer, a first conductive type third nitride-based III-V compound semiconductor layer, an active layer, and a second conductive type fourth nitride-based III-V compound semiconductor layer; and
removing the substrate.

4. A light-emitting diode comprising:
a fifth nitride-based III-V compound semiconductor layer; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in one major surface of the fifth nitride-based III-V compound semiconductor layer located at a side opposite to that of the active layer, convex portions composed of a dielectric substance having a refractive index of 1.0 to 2.3 are buried, and
in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

5. A light source cell unit comprising:
a plurality of arranged cells, each having at least one red light-emitting diode, at least one green light-emitting diode, and at least one blue light-emitting diode;
wherein at least one light-emitting diode of the red light-emitting diode, the green light-emitting diode, and the blue light-emitting diode includes,
a substrate provided with convex portions on one major surface, the convex portions being composed of a dielectric substance which is different from the substrate and which has a refractive index of 1.7 to 2.2;
a fifth nitride-based III-V compound semiconductor layer grown on the substrate without forming a space in a concave portion on the substrate; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

6. A light source cell unit comprising:
a plurality of arranged cells, each having at least one red light-emitting diode, at least one green light-emitting diode, and at least one blue light-emitting diode;
wherein at least one light-emitting diode of the red light-emitting diode, the green light-emitting diode, and the blue light-emitting diode includes,
a fifth nitride-based III-V compound semiconductor layer; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in one major surface of the fifth nitride-based III-V compound semiconductor layer located at a side opposite to that of the active layer, convex portions composed of a dielectric substance having a refractive index of 1.0 to 2.3 are buried, and
in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

7. A light-emitting diode backlight comprising:
a plurality of red light-emitting diodes;
a plurality of green light-emitting diodes; and
a plurality of blue light-emitting diodes, the light-emitting diodes being arranged;
wherein at least one light-emitting diode of the red light-emitting diodes, the green light-emitting diodes, and the blue light-emitting diodes includes,
a substrate provided with convex portions on one major surface, the convex portions being composed of a dielectric substance which is different from the substrate and which has a refractive index of 1.7 to 2.2;
a fifth nitride-based III-V compound semiconductor layer grown on the substrate without forming a space in a concave portion on the substrate; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

8. A light-emitting diode backlight comprising:
a plurality of red light-emitting diodes;
a plurality of green light-emitting diodes; and
a plurality of blue light-emitting diodes, the light-emitting diodes being arranged;
wherein at least one light-emitting diode of the red light-emitting diodes, the green light-emitting diodes, and the blue light-emitting diodes includes,
a fifth nitride-based III-V compound semiconductor layer; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in one major surface of the fifth nitride-based III-V compound semiconductor layer located at a side opposite to that of the active layer, convex portions composed of a dielectric substance having a refractive index of 1.0 to 2.3 are buried, and
in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

9. A light-emitting diode illuminating device comprising:
a plurality of red light-emitting diodes;
a plurality of green light-emitting diodes; and
a plurality of blue light-emitting diodes, the light-emitting diodes being arranged;
wherein at least one light-emitting diode of the red light-emitting diodes, the green light-emitting diodes, and the blue light-emitting diodes includes,
a substrate provided with convex portions on one major surface, the convex portions being composed of a dielectric substance which is different from the substrate and which has a refractive index of 1.7 to 2.2;
a fifth nitride-based III-V compound semiconductor layer grown on the substrate without forming a space in a concave portion on the substrate; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

10. A light-emitting diode illuminating device comprising:
a plurality of red light-emitting diodes;
a plurality of green light-emitting diodes; and
a plurality of blue light-emitting diodes, the light-emitting diodes being arranged;
wherein at least one light-emitting diode of the red light-emitting diodes, the green light-emitting diodes, and the blue light-emitting diodes includes,
a fifth nitride-based III-V compound semiconductor layer; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in one major surface of the fifth nitride-based III-V compound semiconductor layer located at a side opposite to that of the active layer, convex portions composed of a dielectric substance having a refractive index of 1.0 to 2.3 are buried, and
in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

11. A light-emitting diode display comprising:
a plurality of red light-emitting diodes;
a plurality of green light-emitting diodes; and
a plurality of blue light-emitting diodes, the light-emitting diodes being arranged;
wherein at least one light-emitting diode of the red light-emitting diodes, the green light-emitting diodes, and the blue light-emitting diodes includes,
a substrate provided with convex portions on one major surface, the convex portions being composed of a dielectric substance which is different from the substrate and which has a refractive index of 1.7 to 2.2;
a fifth nitride-based III-V compound semiconductor layer grown on the substrate without forming a space in a concave portion on the substrate; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

12. A light-emitting diode display comprising:
a plurality of red light-emitting diodes;
a plurality of green light-emitting diodes; and
a plurality of blue light-emitting diodes, the light-emitting diodes being arranged;
wherein at least one light-emitting diode of the red light-emitting diodes, the green light-emitting diodes, and the blue light-emitting diodes includes,
a fifth nitride-based III-V compound semiconductor layer; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in one major surface of the fifth nitride-based III-V compound semiconductor layer located at a side opposite to that of the active layer, convex portions composed of a dielectric substance having a refractive index of 1.0 to 2.3 are buried, and
in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

13. An electronic apparatus comprising:
at least one light-emitting diode;
wherein said at least one light-emitting diode includes,
a substrate provided with convex portions on one major surface, the convex portions being composed of a dielectric substance which is different from the substrate and which has a refractive index of 1.7 to 2.2;
a fifth nitride-based III-V compound semiconductor layer grown on the substrate without forming a space in a concave portion on the substrate; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

14. An electronic apparatus comprising:
at least one light-emitting diode;
wherein said at least one light-emitting diode includes,
a fifth nitride-based III-V compound semiconductor layer; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in one major surface of the fifth nitride-based III-V compound semiconductor layer located at a side opposite to that of the active layer, convex portions composed of a dielectric substance having a refractive index of 1.0 to 2.3 are buried, and
in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.

15. A light-emitting diode comprising;
a substrate provided with convex portions on one major surface, the convex portions being composed of a dielectric substance which is different from the substrate and which can change its refractive index by applying a voltage thereto;
a fifth nitride-based III-V compound semiconductor layer grown on the substrate without forming a space in a concave portion on the substrate; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in the fifth nitride-based III-V compound semiconductor layer, dislocation generated from the interface with the bottom surface of the concave portion in a direction perpendicular to said one major surface extends to an inclined surface of a triangle portion using the bottom surface of the concave portion as the base or to the vicinity of the inclined surface and is then bent in a direction parallel to said one major surface.

16. A light-emitting diode comprising:
a fifth nitride-based III-V compound semiconductor layer; and
a first conductive type third nitride-based III-V compound semiconductor layer, an active layer, and a second conductive type fourth nitride-based III-V compound semiconductor layer, which are provided on the fifth nitride-based III-V compound semiconductor layer;
wherein in one major surface of the fifth nitride-based III-V compound semiconductor layer located at a side opposite to that of the active layer, convex portions composed of a dielectric substance which can change its refractive index by applying a voltage thereto are buried, and
in the fifth nitride-based III-V compound semiconductor layer, dislocation generated from between the convex portions in said one major surface in a direction perpendicular to said one major surface extends to an inclined surface of a triangle portion using a part between the convex portions as the base or to the vicinity of the inclined surface and is then bent in a direction parallel to said one major surface.
